(19) United States
(12) Patent Application Publication
(10) Pub. No.: US 2004/0217342 A1
(43) Pub. Date: Nov. 4, 2004

(54) Anisotropically conductive connector, production process thereof and application product thereof

(75) Inventors: Terukazu Kokubo, Tokyo (JP); Koji Seno, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: JSR Corporation, Tokyo (JP)

(21) Appl. No.: 10/755,233

(22) Filed: Jan. 13, 2004

(30) Foreign Application Priority Data
Aug. 31, 2001 (JP) 2001-262550

(51) Int. Cl. H01L 29/06

(52) U.S. Cl. 257/9; 264/439; 264/104

(57) ABSTRACT

Disclosed herein are an anisotropically conductive connector, by which positioning, and holding and fixing to a circuit device can be conducted with ease even when the pitch of electrodes of the circuit device to be connected is small, and moreover good conductivity can be achieved as to all conductive parts, and insulating property between adjacent conductive parts can be surely achieved, a production process thereof, and applied products thereof. The anisotropically conductive connector is obtained by forming a molding material layer for the elastic anisotropically conductive film with conductive particles exhibiting magnetism dispersed in a liquid polymeric substance-forming material, which will become an elastic polymeric substance by a curing treatment, within the through-hole in the frame plate and at the inner peripheral edge portion about the through-hole of the frame plate, applying a magnetic field having higher intensity at a portion to become the conductive part for connection and a portion to become the part to be supported in the molding material layer, than any other portion, to the molding material layer, thereby gathering the conductive particles at the portion to become the conductive part for connection in a state that the conductive particles present in the portion to become the part to be supported have been retained in this portion, and orienting them in the thickness-wise direction, and subjecting the molding material layer to a curing treatment.

### BACKGROUND OF THE INVENTION

1. Field of the Invention

The present invention relates to an anisotropically conductive connector suitable for use in, for example, electrical connection between circuit devices and a production process thereof, and application product thereof, and more particularly to an anisotropically conductive connector suitable for use as a connector for respectively conducting electrical inspection of a plurality of integrated circuits formed on a wafer in a state of the wafer and a production process thereof, and application product thereof.

2. Description of the Background Art

An anisotropically conductive elastomer sheet is a sheet exhibiting conductivity only in its thickness-wise direction or having pressure-sensitive conductive conductor parts exhibiting conductivity only in its thickness-wise direction when it is pressurized in the thickness-wise direction. Since the anisotropically conductive elastomer sheet has such features that compact electrical connection can be achieved without using any means such as soldering or mechanical fitting, and that soft connection is feasible with mechanical shock or strain absorbed therein, it is widely used as a connector for achieving electrical connection between a circuit device, for example, a printed circuit board, and a leadless chip carrier, liquid crystal panel or the like in fields of, for example, electronic computers, electronic digital clocks, electronic cameras and computer key boards.

On the other hand, in electrical inspection of circuit devices such as printed circuit boards and semiconductor integrated circuits, in order to achieve electrical connection between electrodes to be inspected formed on one surface of the circuit device, which is an inspection target, and electrodes for inspection formed on the surface of the circuit board for inspection, it is conducted to cause an anisotropically conductive elastomer sheet to intervene between an electrode region to be inspected of an electronic circuit part and an electrode region for inspection of a circuit board for inspection.

As such anisotropically conductive elastomer sheets, there have heretofore been known those of various structures. For example, Japanese Patent Application Laid-Open No. 93393/1976 discloses an anisotropically conductive elastomer sheet (hereinafter referred to as “dispersion type anisotropically conductive elastomer sheet”) obtained by uniformly dispersing metal particles in an elastomer, and Japanese Patent Application Laid-Open No. 147772/1978 discloses an anisotropically conductive elastomer sheet (hereinafter referred to as “uneven distribution type anisotropically conductive elastomer sheet”) obtained by unevenly distributing particles of a conductive magnetic substance in an elastomer to form a great number of conductive parts extending in a thickness-wise direction thereof and insulating parts for mutually insulating them. Further, Japanese Patent Application Laid-Open No. 250906/1986 discloses an uneven distribution type anisotropically conductive elastomer sheet with a difference in level defined between the surface of each conductive part and an insulating part.

In the uneven distribution type anisotropically conductive elastomer sheets, the conductive parts are formed in accordance with a pattern antipodal to a pattern of electrodes of a circuit device to be connected, and so it is advantageous compared with the dispersion type anisotropically conductive elastomer sheet in that electrical connection between electrodes can be achieved with high reliability even to a circuit device or the like small in the arrangement pitch of electrodes to be connected, i.e., small in the center distance between adjacent electrodes.

In such an uneven distribution type anisotropically conductive elastomer sheet, it is necessary to hold and fix it in a particular positional relation to an electronic circuit part in an electrically connecting operation to a circuit device to be connected.

However, the anisotropically conductive elastomer sheet is flexible and easy to be deformed, and so it is low in handling property. In addition, with the miniaturization or high-density wiring of electric products in recent years, circuit devices used therein tend to arrange electrodes at a higher density because the number of electrodes increases and the arrangement pitch of the electrodes becomes smaller. Therefore, the positioning and the holding and fixing of the uneven distribution type anisotropically conductive elastomer sheet are going to be difficult upon electrical connection between circuit devices and electrical connection to electrodes for inspection in electrical inspection of a circuit device.

In the electrical inspection of a circuit device, a burn-in test and a heat cycle test that electrical inspection of a circuit device as an object of inspection is practiced in a state heated to a prescribed temperature for the purpose of developing latent defects of such a circuit device are carried out. In such a test, there is a problem that even when the necessary positioning, and holding and fixing of the circuit device to the uneven distribution type anisotropically conductive elastomer sheet has been realized once, the state of electrical connection is changed, and the stably connected state is not retained when they are subjected to thermal hysteresis by temperature change, since the degrees of stress by thermal expansion and heat shrinkage are different between a material making up the circuit device as the object of the inspection and a material making up the uneven distribution type anisotropically conductive elastomer sheet.

In order to solve such a problem, an anisotropically conductive connector composed of a metal-made frame plate having an opening and an anisotropically conductive sheet arranged in the opening of this frame plate and supported at its peripheral edge by an opening edge about the frame plate has been proposed (Japanese Patent Application Laid-Open No. 40224/1999).

This anisotropically conductive connector is generally produced in the following manner.

As illustrated in FIG. 19, a mold for molding an anisotropically conductive elastomer sheet, which is composed of a top force 80 and a bottom force 85 making a pair therewith, is provided, a frame plate 90 having an opening 91 is arranged in alignment in this mold, and a molding material with conductive particles exhibiting magnetism dispersed in a polymeric substance-forming material, which will become an elastic polymeric substance by a curing treatment, is fed into a region including the opening 91 of the frame plate 90 and an opening edge thereabout to form a molding material layer 95. Here, the conductive particles P contained in the molding material layer 95 are in a state dispersed in the molding material layer 95.

Both top force 80 and bottom force 85 in the mold respectively have molding surfaces composed of a plurality of ferromagnetic substance layers 81 or 86 formed in accordance with a pattern corresponding to a pattern of conductive parts of an anisotropically conductive elastomer sheet to be molded and non-magnetic substance layers 82 or 87 formed at other potions than the portions at which the ferromagnetic substance layers 81 or 86 have been respectively formed, and their corresponding ferromagnetic substance layers 81 and 86 are arranged in opposed relation to each other.

A pair of, for example, electromagnets are then arranged on an upper surface of the top force 80 and an lower surface of the bottom force 85, and the electromagnets are operated, thereby a magnetic field having higher intensity at portions between ferromagnetic substance layers 81 of the top force 80 and their corresponding ferromagnetic substance layers 86 of the bottom force 85, i.e., portions to become conductive parts, than the other portions, is applied to the molding material layer 95 in a thickness-wise direction thereof. As a result, the conductive particles P dispersed in the molding material layer 95 are gathered at the portions to which the magnetic field of the higher intensity is being applied, i.e., the portions between ferromagnetic substance layers 81 of the top force 80 and their corresponding ferromagnetic substance layers 86 of the bottom force 85, and further oriented so as to align in the thickness-wise direction. In this state, the molding material layer 95 is subjected to a curing treatment, whereby an anisotropically conductive elastomer sheet composed of a plurality of conductive parts, in which the conductive particles P are contained in a state oriented so as to align in the thickness-wise direction, and insulating parts for mutually insulating these conductive parts is molded in a state that its peripheral edge has been supported by the opening edge about the frame plate, thereby producing an anisotropically conductive connector.

According to such an anisotropically conductive connector, it is hard to be deformed and easy to handle because the anisotropically conductive elastomer sheet is supported by the metal-made frame plate. In addition, a positioning mark (for example, a hole) is formed in the support, whereby the positioning and the holding and fixing to a circuit device can be easily conducted upon an electrically connecting operation to the circuit device. Further, a material low in coefficient of thermal expansion is used as a material for forming the support, whereby the thermal expansion and heat shrinkage of the anisotropically conductive sheet are restrained by the support, so that a good electrically connected state is stably retained even when the anisotropically conductive sheet and circuit device are subjected to thermal hysteresis by temperature change.

However, it has been found that such an anisotropically conductive connector involves the following problems.

(1) When a magnetic field is applied in the thickness-wise direction of the molding material layer 95 in the molding step of the anisotropically conductive elastomer sheet, conductive particles P present in a portion located inside among portions, which will become conductive parts in the molding material layer 95, for example, a portion (hereinafter referred to as “conductive part-forming portion X”) represented by a character X in FIG. 19, and surroundings thereof are gathered at the conductive part-forming portion X. However, not only conductive particles P present in a portion located most outside among the portions, which will become conductive parts, for example, a portion (hereinafter referred to as “conductive part-forming portion Y”) represented by a character Y in FIG. 19, and surroundings thereof, but also conductive particles P present above and below the frame plate 90 are gathered at the conductive part-forming portion Y. As a result, a conductive part formed at the conductive part-forming portion Y is in a state that the conductive particles P have been contained in excess, so that its insulating property with an adjacent conductive part is not achieved, and so these conductive parts cannot be effectively used. In order to prevent the conductive particles P from being excessively contained in the conductive part formed at the conductive part-forming portion Y, it is also considered to reduce the content of the conductive particles in the molding material. However, the content of the conductive particles in any other conductive part, for example, the conductive part formed at the conductive part-forming portion X becomes too low, so that good conductivity cannot be achieved at such a conductive part.

(2) In the anisotropically conductive connector described above, a peripheral portion of the anisotropically conductive elastomer sheet is used as a portion to be supported to be supported by the frame plate, so that no conductive part for being electrically connected to, for example, an electrode of a circuit device, is formed at all at the peripheral portion. Accordingly, an insulating part of quite large region is present at the peripheral portion of the anisotropically conductive elastomer sheet, therefore, the surface of the peripheral portion of the anisotropically conductive elastomer sheet is charged with static electricity according to the manner of use and service environment of the anisotropically conductive connector to cause various problems.

For example, when the anisotropically conductive connector is used in electrical inspection of a circuit device, the anisotropically conductive connector is caused to intervene between the circuit device to be inspected and a circuit board for inspection, and the anisotropically conductive elastomer sheet in this anisotropically conductive connector is pressurized, thereby achieving electrical connection between the circuit device to be inspected and the circuit board for inspection to conduct the electrical inspection. Electric charges are easy to be generated by the pressurizing operation and a separating operation, and electric charges are accumulated on the surface of the peripheral portion in the anisotropically conductive elastomer sheet by continuously conducting the electrical inspection of circuit devices many times, resulting in being charged with static electricity of high voltage.

When the static electricity is discharged through the conductive parts of the anisotropically conductive elastomer sheet, not only the conductive parts of the anisotropically conductive elastomer sheet and a wiring circuit of the circuit board for inspection, but also the circuit devices as objects of the inspection are adversely affected. As a result, there is a possibility that anisotropically conductive elastomer sheet and circuit board for inspection may be damaged, or the circuit device to be inspected as the object of the inspection may be broken.

In addition, when electric charges are accumulated on the surface of the anisotropically conductive elastomer sheet to charge the surface with static electricity, the circuit device to be inspected sticks to the anisotropically conductive elastomer sheet, so that it is difficult to smoothly conduct the inspecting operation.

### SUMMARY OF THE INVENTION

The present invention has been made on the basis of the foregoing circumstances and has as its first object the provision of an anisotropically conductive connector that positioning, and holding and fixing to a circuit device to be connected can be conducted with ease even when the pitch of electrodes of the circuit device is small, good conductivity can be achieved with certainty as to all conductive parts, and moreover insulating property between adjacent conductive parts can be achieved with certainty, and a production process thereof.

A second object of the present invention is to provide an anisotropically conductive connector that a good electrically connected state is stably retained even by environmental changes such as thermal hysteresis by temperature change, in addition to the above object, and a production process thereof.

A third object of the present invention is to provide an anisotropically conductive connector that can exclude adverse influence by static electricity, in addition to the above objects, and a production process thereof.

A fourth object of the present invention is to provide a probe member, by which positioning, and holding and fixing to a circuit device as an object of inspection can be conducted with ease even when the pitch of electrodes to be inspected of the circuit device is small, and which has high reliability on connection to each electrode to be inspected.

A fifth object of the present invention is to provide an electrical inspection apparatus for circuit devices, by which positioning, and holding and fixing to a circuit device as an object of inspection can be conducted with ease even when the pitch of electrodes to be inspected of the circuit device is small, and which has high reliability on connection to each electrode to be inspected.

A sixth object of the present invention is to provide a conductive connection structure having high reliability on connection between circuit devices.

According to the present invention, there is thus provided a process for producing an anisotropically conductive connector comprising a frame plate having a through-hole extending in a thickness-wise direction thereof and an elastic anisotropically conductive film arranged within the through-hole in the frame plate and supported by an inner peripheral edge portion about the through-hole, in which the elastic anisotropically conductive film is composed of a functional part composed of a conductive part for connection containing conductive particles exhibiting magnetism at high density and extending in a thickness-wise direction of the film and an insulating part formed around the conductive part, and a part to be supported integrally formed at a peripheral edge of the functional part and fixed to the inner peripheral edge portion about the through-hole in the frame plate, the process comprises the steps of:

forming a molding material layer for the elastic anisotropically conductive film with conductive particles exhibiting magnetism dispersed in a liquid polymeric substance-forming material, which will become an elastic polymeric substance by a curing treatment, within the through-hole in the frame plate and at the inner peripheral edge portion about the through-hole,

applying a magnetic field having higher intensity at a portion to become the conductive part for connection and a portion to become the part to be supported, than any other portion, to the molding material layer, thereby gathering the conductive particles in the molding material layer at the portion to become the conductive part for connection in a state that at least the conductive particles present in the portion to become the part to be supported in the molding material layer have been retained in this portion, and orienting them in the thickness-wise direction, and in this state,

subjecting the molding material layer to a curing treatment to form the elastic anisotropically conductive film.

In the production process of the anisotropically conductive connector according to the present invention, a frame plate having a plurality of through-holes may be used, and elastic anisotropically conductive films are formed in the respective through-holes in the frame plate.

An elastic anisotropically conductive film having a functional part, in which a plurality of conductive parts for connection are arranged in a state mutually insulated by an insulating part, may be formed.

In the production process of the anisotropically conductive connector according to the present invention, it may be preferable that the frame plate should exhibit magnetism at least at the inner peripheral edge portion about the through-hole, and the inner peripheral edge portion about the frame plate be magnetized, thereby applying a magnetic field to the portion to become the part to be supported of the molding material layer.

The inner peripheral edge portion about the through-hole in the frame plate may preferably have a saturation magnetization of at least 0.1 Wb/m².

The frame plate may preferably be formed by a magnetic substance.

The frame plate may preferably have a coefficient of linear thermal expansion of at most 3×10⁻⁵/K.

In the production process of the anisotropically conductive connector according to the present invention, the through-hole in the frame plate may preferably satisfy the following expression (1):

0.02≦(S₂/S₁)≦0.5 Expression (1)

wherein S₁ is a sectional area in a plane direction of the through-hole, and S₂ is a total sectional area in a plane direction of the conductive part(s) for connection in the elastic anisotropically conductive film formed in the through-hole.

In the production process of the anisotropically conductive connector according to the present invention, the shortest clearance between an inner peripheral edge surface of the through-hole in the frame plate and a conductive part for connection to be formed may preferably be at least 0.25 times as much as the thickness of the conductive part for connection.

Conductive particles having a saturation magnetization of at least 0.1 Wb/m² may preferably be used as the conductive particles contained in the molding material layer and exhibiting magnetism.

The production process of the anisotropically conductive connector according to the present invention may preferably satisfy the following expression (2):

0.1≦(V₁/V₂)≦0.5 Expression (2)

wherein V₁ is a total volume of the conductive particles contained in the molding material layer, and V₂ is a total volume of the conductive part(s) for connection in the elastic anisotropically conductive film to be formed.

In the production process of the anisotropically conductive connector according to the present invention, a magnetic flux density at the portion to become the part to be supported in a state that the magnetic field has been applied to the molding material layer may preferably be 30 to 150% of a magnetic flux density at the portion to become the conductive part for connection.

In the production process of the anisotropically conductive connector according to the present invention, it may be preferable that a magnetic field be applied to the portion to become the part to be supported in the molding material layer, whereby the molding material layer be subjected to a curing treatment in a state that the conductive particles present at least in the portion to become the part to be supported are oriented in the thickness-wise direction, to form an elastic anisotropically conductive film having a conductive part for charge elimination in the part to be supported.

According to the present invention, there is also provided an anisotropically conductive connector produced in accordance with the production process described above.

According to the present invention, there is further provided a probe member suitable for use in electrical inspection of a circuit device, which comprises:

the above-described anisotropically conductive connector having elastic anisotropically conductive films, in which conductive parts have been formed in accordance with a pattern corresponding to a pattern of electrodes to be inspected of the circuit device as an object of inspection.

The probe member according to the present invention may comprise a circuit board for inspection, on the surface of which inspection electrodes have been formed in accordance with a pattern corresponding to a pattern of electrodes to be inspected, the anisotropically conductive connector arranged on the surface of the circuit board for inspection and a sheet-like connector arranged on the surface of the anisotropically conductive connector,

wherein the sheet-like connector is composed of an insulating sheet and a plurality of electrode structures each extending through in a thickness-wise direction of the insulating sheet and arranged in accordance with a pattern corresponding to the pattern of the electrodes to be inspected.

According to the present invention, there is still further provided an electrical inspection apparatus for circuit devices, comprising the probe member described above, wherein electrical connection to electrodes to be inspected of a circuit device as an object of inspection is achieved through the probe member.

In the electrical inspection apparatus for circuit devices according to the present invention, it may be preferable that the apparatus should have a heating means for heating the circuit device as the object of inspection, and the electrical inspection of the circuit device be carried out in a state that the circuit device has been heated to a prescribed temperature by the heating means.

According to the present invention, there is yet still further provided a conductive connection structure obtained by being electrically connected through the anisotropically conductive connector described above.

According to the present invention, since the molding material layer is subjected to a curing treatment in a state that the conductive particles present in the portion to become the part to be supported in the molding material layer have been retained in this portion by applying a magnetic field having high intensity to the portion to become the part to be supported, in the molding of an elastic anisotropically conductive film, the conductive particles present in the portion to become the part to be supported in the molding material layer, i.e., portions located above and below the inner peripheral edge portion about the through-hole in the frame plate are not gathered at the portion to become the conductive part for connection. As a result, it can be prevented that the conductive particles are contained in excess in the conductive parts for connection located most outside among the conductive parts for connection in the resulting anisotropically conductive film. Accordingly, a proper amount of the conductive particles can be contained in the respective conductive parts for connection, so that an anisotropically conductive connector having good conductivity at all the conductive parts for connection in the elastic anisotropically conductive film and necessary insulating property between adjacent conductive parts for connection is provided.

In addition, the conductive particles present in the portion to become the part to be supported in the molding material layer are oriented in the thickness-wise direction to form the elastic anisotropically conductive film having the conductive part for charge elimination in the part to be supported, whereby static electricity generated on the surface of the elastic anisotropically conductive film can be eliminated through the conductive part for charge elimination, so that it is prevented or inhibited that electric charges are accumulated on the surface of the elastic anisotropically conductive film. As a result, adverse influence by static electricity can be excluded.

### BRIEF DESCRIPTION OF THE DRAWING

The above and other objects, features and advantages of the present invention will become apparent from the following description and the appended claims, taken in conjunction with the accompanying drawings, in which:

FIG. 1 is a plan view illustrating an exemplary anisotropically conductive connector according to the present invention.

FIG. 2 is a plan view illustrating, on an enlarged scale, a part of the anisotropically conductive connector shown in FIG. 1.

FIG. 3 is a plan view illustrating, on an enlarged scale, an elastic anisotropically conductive film in the anisotropically conductive connector shown in FIG. 1.

FIG. 4 is a cross-sectional view illustrating, on an enlarged scale, the elastic anisotropically conductive film in the anisotropically conductive connector shown in FIG. 1.

FIG. 5 is a cross-sectional view illustrating the construction of an exemplary mold for molding of an elastic anisotropically conductive film.

FIG. 6 is a cross-sectional view illustrating, on an enlarged scale, a part of the mold shown in FIG. 5.

FIG. 7 is a cross-sectional view illustrating a step of coating a molding surface of a top force with a molding material by a screen-printing method.

FIG. 8 is a cross-sectional view illustrating a state that the molding material has been applied to molding surfaces of the top force and a bottom force to form molding material layers.

FIG. 9 is a cross-sectional view illustrating a state that a frame plate has been arranged through spacers between the top force and the bottom force, on the molding surface of which the molding material layers have been formed.

FIG. 10 is a cross-sectional view illustrating a state that a molding material layer of the intended form has been formed between the top force and the bottom force.

FIG. 11 is a cross-sectional view illustrating, on an enlarged scale, the molding material layer shown in FIG. 10.

FIG. 12 is a cross-sectional view illustrating a state that a magnetic field having a strength distribution in a thickness-wise direction of the molding material layer has been formed in the molding material layer shown in FIG. 11.

FIG. 13 is a plan view illustrating another exemplary anisotropically conductive connector according to the present invention.

FIG. 14 is a cross-sectional view illustrating, on an enlarged scale, an elastic anisotropically conductive film in the anisotropically conductive connector shown in FIG. 13.

FIG. 15 is a cross-sectional view illustrating the construction of an exemplary electrical inspection apparatus for circuit devices according to the present invention.

FIG. 16 is a cross-sectional view illustrating the construction of a principal part of an exemplary probe member according to the present invention.

FIG. 17 is a cross-sectional view illustrating the construction of an exemplary conductive connection structure according to the present invention.

FIG. 18 illustrates measuring places of a surface potential in an anisotropically conductive connector in Examples.

FIG. 19 is a cross-sectional view illustrating a state that a frame plate has been arranged within a mold in a process for producing a conventional anisotropically conductive connector, and a molding material layer has been formed.

### DETAILED DESCRIPTION OF THE PREFERRED EMBODIMENTS

The embodiments of the present invention will hereinafter be described in details.

[Anisotropically Conductive Connector]

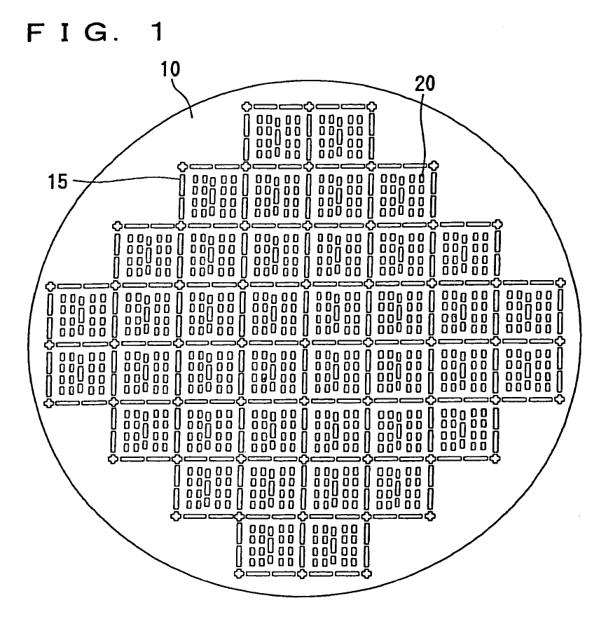

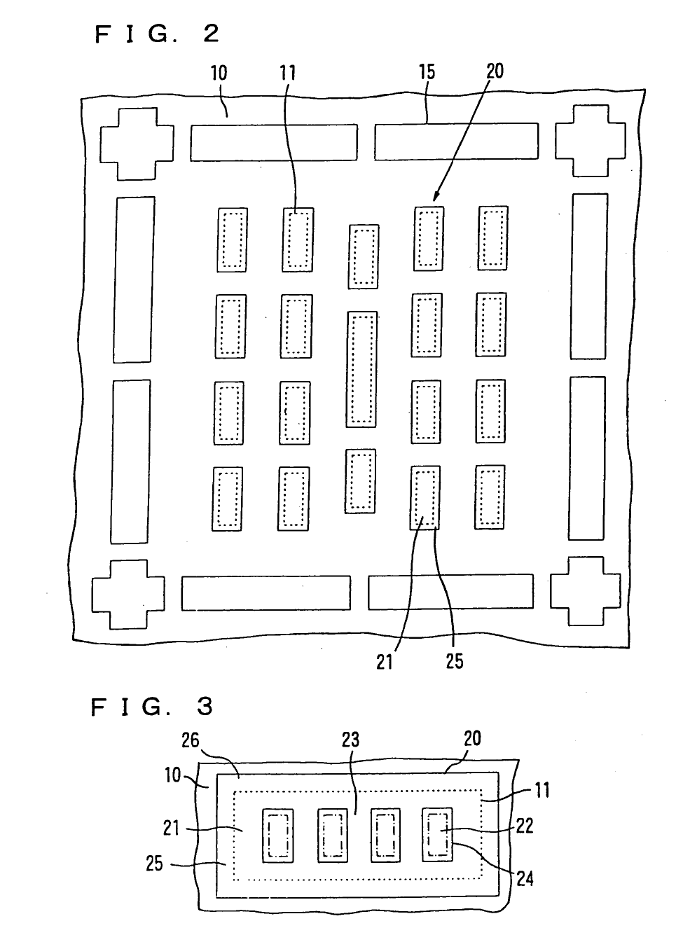

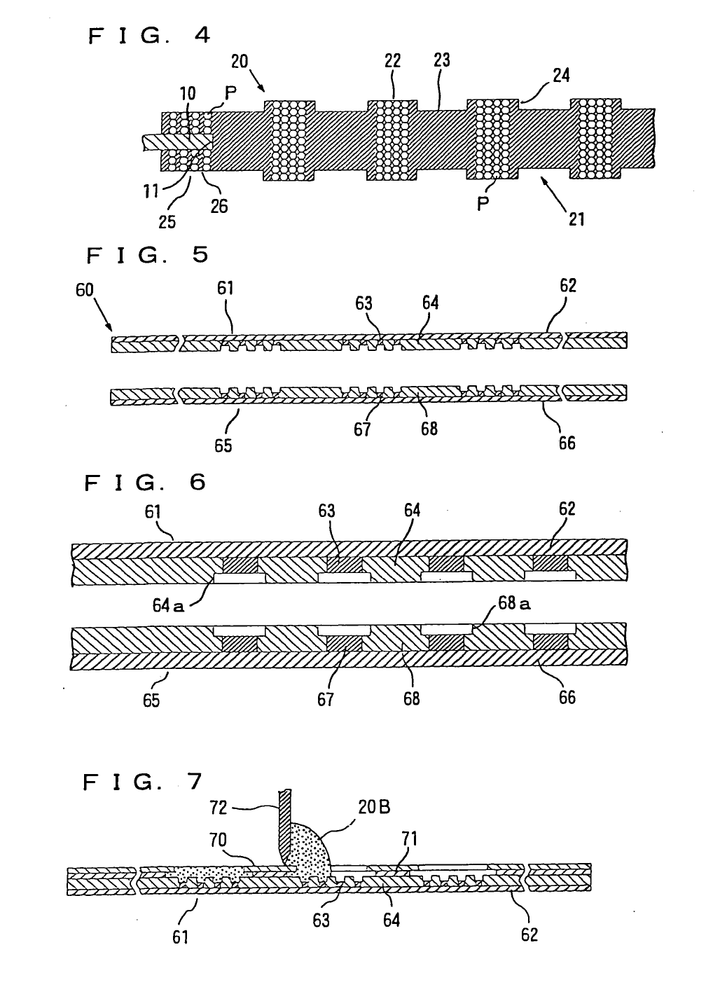

FIG. 1 is a plan view illustrating an exemplary anisotropically conductive connector according to the present invention, FIG. 2 is a plan view illustrating, on an enlarged scale, a part of the anisotropically conductive connector shown in FIG. 1, FIG. 3 is a plan view illustrating, on an enlarged scale, an elastic anisotropically conductive film in the anisotropically conductive connector shown in FIG. 1, and FIG. 4 is a cross-sectional view illustrating, on an enlarged scale, the elastic anisotropically conductive film in the anisotropically conductive connector shown in FIG. 1.

The anisotropically conductive connector shown in FIG. 1 is that used in conducting electrical inspection of each of, for example, a plurality of integrated circuits formed on a wafer in a state of the wafer and has a frame plate 10 in which a plurality of through-holes 11 (indicated by broken lines) each extending through in a thickness-wise direction of the frame plate have been formed as illustrated in FIG. 2. The through-holes 11 in this frame plate 10 are formed in accordance with a pattern of electrode regions in which electrodes to be inspected of the integrated circuits in the wafer as an object of inspection have been formed. Elastic anisotropically conductive films 20 having conductivity in the thickness-wise direction thereof are arranged in the respective through-holes 11 in the frame plate 10 in a state respectively supported by the inner peripheral edge portions about the through-holes 11 in the frame plate 10. In the frame plate 10 of this embodiment, are formed holes 15 for venting upon forming the elastic anisotropically conductive films 20 within the through-holes 11 in the frame plate 10 in a production process, which will be described subsequently.

As illustrated in FIG. 3, each of the elastic anisotropically conductive films 20, a base material of which is composed of an elastic polymeric substance, has a functional part 21 composed of a plurality of conductive parts 22 for connection each extending in the thickness-wise direction (direction perpendicular to the paper in FIG. 3) of the film and insulating parts 23 formed around the respective conductive parts 22 for connection and mutually insulating these conductive parts 22 for connection. The functional part 21 is arranged so as to be located in the through-hole 11 in the frame plate 10. A part 25 to be supported, which is fixed to and supported by an inner peripheral edge portion about the through-hole 11 in the frame plate 10, is integrally continuously formed at a peripheral edge of the functional part 21. More specifically, the part 25 to be supported in this embodiment is shaped in a forked form and fixed and supported in a closely contacted state so as to grasp the inner peripheral edge portion about the through-hole 11 in the frame plate 10.

In the conductive parts 22 for connection in the functional part 21 of the elastic anisotropically conductive film 20, conductive particles P exhibiting magnetism are contained at high density in a state oriented so as to align in the thickness-wise direction as illustrated in FIG. 4. On the other hand, the insulating parts 23 do not contain the conductive particles P at all or scarcely contain them. In the embodiment illustrated, projected portions 24 protruding from other surfaces than portions, at which the conductive parts 22 for connection and peripheral portions thereof are located, are formed at those portions on both sides of the functional part 21 in the elastic anisotropically conductive film 20.

The part 25 to be supported in the elastic anisotropically conductive film 20 contains the conductive particles P. In the part 25 to be supported in this embodiment, the conductive particles P are contained in a state oriented so as to align in the thickness-wise direction, whereby a conductive part 26 for charge elimination, in which a conductive path is formed in a thickness-wise direction of the part by the conductive particles P, is formed over the part 25 to be supported. In the present invention, however, it is not essential to form the conductive part 26 for charge elimination in the part 25 to be supported of the elastic anisotropically conductive film 20.

The thickness of the frame plate 10 varies according to the material thereof, and is preferably 30 to 600 μm, more preferably 40 to 400 μm.

If this thickness is smaller than 30 μm, the strength required upon use of the resulting anisotropically conductive connector is not achieved, and the anisotropically conductive connector tends to be low in the durability. In addition, such stiffness as the form of the frame plate 10 is retained is not achieved, and the handling property of the anisotropically conductive connector becomes low. If the thickness exceeds 600 μm on the other hand, the elastic anisotropically conductive films 20 formed in the through-holes 11 become too great in thickness, and it may be difficult in some cases to achieve good conductivity in the conductive parts 22 for connection and insulating property between adjacent conductive parts 22 for connection.

The form and size of the through-holes 11 in the frame plate 10 in the plane direction are designed according to the size, pitch and pattern of electrodes to be inspected in a wafer as an object of inspection.

The overall thickness (thickness of the conductive part 22 for connection in the illustrated embodiment) of the elastic anisotropically conductive film 20 is preferably 50 to 3,000 μm, more preferably 70 to 2,500 μm, particularly preferably 100 to 2,000 μm. When this thickness is 50 μm or greater, an elastic anisotropically conductive film 20 having sufficient strength is provided with certainty. When this thickness is 3,000 μm or smaller on the other hand, a conductive part 22 for connection having necessary conductive properties is provided with certainty.

The projected height of the projected portions 24 is preferably at least 10% in total of the thickness in the projected portion 24, more preferably at least 20%. Projected portions 24 having such a projected height are formed, whereby the conductive parts 22 for connection are sufficiently compressed by small pressing force, so that good conductivity is surely achieved.

The projected height of the projected portion 24 is preferably at most 100%, more preferably at most 70% of the shortest width or diameter of the projected portion 24. Projected portions 24 having such a projected height are formed, whereby the projected portions are not buckled when they are pressurized, so that the prescribed conductivity is surely achieved.

The thickness (thickness of one of the forked portion in the illustrated embodiment) of the part 25 to be supported is preferably 5 to 600 μm, more preferably 10 to 500 μm, particularly preferably 20 to 400 μm.

It is not essential to form the part 25 to be supported in the forked form, and it may be fixed to only one surface of the frame plate 10.

When a sectional area in a plane direction of each through-hole 11 in the frame plate 10 is regarded as S₁, and a total sectional area in a plane direction of the conductive parts 22 for connection in the elastic anisotropically conductive film 20 formed in the through-hole 11 is regarded as S₂, the through-hole 11 is preferably designed in such a manner that a value of a ratio (S₂/S₁) is 0.02 to 0.5. If the value of this ratio (S₂/S₁) is lower than 0.02, the amount of the conductive particles gathered at the portion(s) to become the conductive part(s) for connection in the molding material layer in the production process, which will be described subsequently, tends to become too great. As a result, it may be difficult in some cases to retain insulating property between adjacent conductive parts 22 for connection in the resulting elastic anisotropically conductive film 20. If the value of this ratio (S₂/S₁) exceeds 0.5 on the other hand, the amount of the conductive particles gathered at the portion(s) to become the conductive part(s) for connection by applying a magnetic field to the molding material layer in the production process, which will be described subsequently, tends to become too small. As a result, it may be difficult in some cases to provide any conductive part 22 for connection having sufficient conductivity.

The shortest clearance between an inner peripheral edge surface of the through-hole 11 in the frame plate and the conductive part 22 for connection in the elastic anisotropically conductive film 20 is preferably at least 0.25 times as much as the thickness of the conductive part 22 for connection. If the shortest clearance is shorter than the 0.25 times of the thickness of the conductive part 22 for connection, the conductive part 22 for connection is not sufficiently compressed in the thickness-wise direction, so that good conductivity may not be achieved by small pressing force in some cases. In addition, when that composed of a magnetic substance is used as the frame plate 10, the amount of the conductive particles gathered at the portion to become the part to be supported in the production process, which will be described subsequently, tends to become too great. As a result, it may be difficult in some cases to provide any conductive parts 22 having sufficient conductivity.

No particular limitation is imposed on a material for forming the frame plate 10 so far as it has such stiffness as the resulting frame plate 10 is hard to be deformed, and the form thereof is stably retained. For example, various kinds of materials such as metallic materials, ceramic materials and resin materials may be used. When the frame plate 10 is formed by, for example, a metallic material, an insulating film may be formed on the surface of the frame plate 10.

Specific examples of the metallic material for forming the frame plate 10 include metals such as iron, copper, nickel, chromium, cobalt, magnesium, manganese, molybdenum, indium, lead, palladium, titanium, tungsten, aluminum, gold, platinum and silver, and alloys or alloy steels composed of a combination of at least two of these metals.

Specific examples of the resin material forming the frame plate 10 include liquid crystal polymers and polyimide resins.

The frame plate 10 may preferably be that exhibiting magnetism at least at the inner peripheral edge portion about the through-hole 11 thereof, i.e., a portion supporting the elastic anisotropically conductive film 20 in that a magnetic field having higher intensity at the portion to become the part 25 to be supported in the molding material layer than any other portion can be applied to that portion with ease in the production process, which will be described subsequently. Specifically, that having a saturation magnetization of at least 0.1 Wb/m² is preferred. In particular, the whole frame plate 10 is preferably formed by a magnetic substance in that the frame plate 10 is easy to be produced.

Specific examples of the magnetic substance forming such a frame plate 10 include iron, nickel, cobalt, alloys of these magnetic metals, and alloys or alloy steels of these magnetic metals with any other metal.

It is also preferable to use a material having a coefficient of linear thermal expansion of at most 3×10⁻⁵/K, more preferably 2×10⁻⁵ down to 1×10⁻⁶/K, particularly preferably 6×10⁻⁶ down to 1×10⁻⁶/K as a material for forming the frame plate 10.

Specific examples of such a material include alloys or alloy steels of magnetic metals, such as Invar alloys such as Invar, Elinvar alloys such as Elinvar, Superinvar, covar, and 42 alloy.

The elastic polymeric substance forming the elastic anisotropically conductive films 20 is preferably a heat-resistant polymeric substance having a crosslinked structure. As a curable polymeric substance-forming material usable for obtaining such a crosslinked polymeric substance, various materials may be used. Specific examples thereof include silicone rubber, conjugated diene rubbers such as polybutadiene rubber, natural rubber, polyisoprene rubber, styrene-butadiene polymer rubber and acrylonitrile-butadiene copolymer rubber, and hydrogenated products thereof; block copolymer rubbers such as styrene-butadiene-diene block copolymer rubber and styrene-isoprene block copolymers, and hydrogenated products thereof; and besides chloroprene rubber, urethane rubber, polyester rubber, epichlorohydrin rubber, ethylene-propylene copolymer rubber, ethylene-propylene-diene copolymer rubber and soft liquid epoxy rubber.

Among these, silicone rubber is preferred from the viewpoints of molding and processing ability and electrical properties.

The silicone rubber is preferably that obtained by crosslinking or condensing liquid silicone rubber. The liquid silicone rubber preferably has a viscosity not higher than 10⁵ poises as measured at a shear rate of 10⁻¹ sec and may be any of condensation type, addition type and those having a vinyl group or hydroxyl group. As specific examples thereof, may be mentioned dimethyl silicone raw rubber, methylvinyl silicone raw rubber and methylphenylvinyl silicone raw rubber.

Among these, vinyl group-containing liquid silicone rubber (vinyl group-containing dimethyl polysiloxane) is generally obtained by subjecting dimethyldichlorosilane or dimethyldialkoxysilane to hydrolysis and condensation reaction in the presence of dimethylvinylchlorosilane or dimethylvinylalkoxysilane and then fractionating the reaction product by, for example, repeated dissolution-precipitation.

Liquid silicone rubber having vinyl groups at both terminals thereof is obtained by subjecting a cyclic siloxane such as octamethylcyclotetrasiloxane to anionic polymerization in the presence of a catalyst, using, for example, dimethyldivinylsiloxane as a polymerization terminator and suitably selecting other reaction conditions (for example, amounts of the cyclic siloxane and polymerization terminator). As the catalyst for the anionic polymerization used herein, may be used an alkali such as tetramethylammonium hydroxide or n-butyl-phosphonium hydroxide, or a silanolate solution thereof. The reaction is conducted at a temperature of, for example, 80 to 130° C.

Such a vinyl group-containing dimethyl polysiloxane preferably has a molecular weight Mw (weight average molecular weight as determined in terms of standard polystyrene; the same shall apply hereinafter) of 10,000 to 40,000. It also preferably has a molecular weight distribution index (a ratio Mw/Mn of weight average molecular weight Mw as determined in terms of standard polystyrene to number average molecular weight Mn as determined in terms of standard polystyrene; the same shall apply hereinafter) of at most 2 from the viewpoint of the heat resistance of the resulting elastic anisotropically conductive films 20.

On the other hand, hydroxyl group-containing liquid silicone rubber (hydroxyl group-containing dimethyl polysiloxane) is generally obtained by subjecting dimethyldichlorosilane or dimethyldialkoxysilane to hydrolysis and condensation reaction in the presence of dimethylhydrochlorosilane or dimethylhydroalkoxysilane and then fractionating the reaction product by, for example, repeated dissolution-precipitation.

The hydroxyl group-containing liquid silicone rubber is also obtained by subjecting a cyclic siloxane to anionic polymerization in the presence of a catalyst, using, for example, dimethylhydrochlorosiloxane, methyldihydrochlorosilane or dimethylhydroalkoxysilane as a polymerization terminator and suitably selecting other reaction conditions (for example, amounts of the cyclic siloxane and polymerization terminator). As the catalyst for the anionic polymerization, may be used an alkali such as tetramethylammonium hydroxide or n-butyl-phosphonium hydroxide or a silanolate solution thereof. The reaction is conducted at a temperature of, for example, 80 to 130° C.

Such a hydroxyl group-containing dimethyl polysiloxane preferably has a molecular weight Mw of 10,000 to 40,000. It also preferably has a molecular weight distribution index of at most 2 from the viewpoint of the heat resistance of the resulting elastic anisotropically conductive films 20.

In the present invention, either one of the above-described vinyl group-containing dimethyl polysiloxane or hydroxyl group-containing dimethyl polysiloxane may be used, or both may be used in combination.

A curing catalyst for curing the polymeric substance-forming material may be contained in the polymeric substance-forming material. As such a curing catalyst, may be used an organic peroxide, fatty acid azo compound, hydrosilylated catalyst or the like.

Specific examples of the organic peroxide used as the curing catalyst include benzoyl peroxide, bisdicyclobenzoyl peroxide, dicumyl peroxide and di-tert-butyl peroxide.

Specific examples of the fatty acid azo compound used as the curing catalyst include azobisisobutyronitrile.

Specific examples of that used as the catalyst for hydrosilylation reaction include publicly known catalysts such as platinic chloride and salts thereof, platinum-unsaturated group-containing siloxane complexes, vinylsiloxane-platinum complexes, platinum-1,3-divinyltetramethyldisiloxane complexes, complexes of triorganophosphine or phosphine and platinum, acetyl acetate platinum chelates, and cyclic diene-platinum complexes.

The amount of the curing catalyst used is suitably selected in view of the kind of the polymeric substance-forming material, the kind of the curing catalyst and other curing treatment conditions. However, it is generally 3 to 15 parts by weight per 100 parts by weight of the polymeric substance-forming material.

As the conductive particles P contained in the conductive parts 22 for connection and the parts 25 to be supported in the elastic anisotropically conductive films 20, those exhibiting magnetism are preferably used in that such conductive particles P can be easily moved in the molding material for forming the elastic anisotropically conductive films 20 by the process, which will be described subsequently. Specific examples of such conductive particles P exhibiting magnetism include particles of metals exhibiting magnetism, such as iron, nickel and cobalt, particles of alloys thereof, particles containing such a metal, particles obtained by using these particles as core particles and plating surfaces of the core particles with a metal having good conductivity, such as gold, silver, palladium or rhodium, particles obtained by using particles of a non-magnetic metal, particles of an inorganic substance, such as glass beads, or particles of a polymer as core particles and plating surfaces of the core particles with a conductive magnetic substance such as nickel or cobalt, and particles obtained by coating the core particles with both conductive magnetic substance and good-conductive metal.

Among these, particles obtained by using nickel particles as core particles and plating their surfaces with a metal having good conductivity, such as gold or silver are preferably used.

No particular limitation is imposed on the means for coating the surfaces of the core particles with the conductive metal. However, for example, the coating may be conducted by electroless plating.

When those obtained by coating the surfaces of the core particles with the conductive metal are used as the conductive particles P, the coating rate (proportion of an area coated with the conductive metal to the surface area of the core particles) of the conductive metal on the particle surfaces is preferably at least 40%, more preferably at least 45%, particularly preferably 47 to 95% from the viewpoint of achieving good conductivity.

The coating amount of the conductive metal is preferably 2.5 to 50% by weight, more preferably 3 to 45% by weight, further preferably 3.5 to 40% by weight, particularly preferably 5 to 30% by weight based on the core particles.

The particle diameter of the conductive particles P is preferably 1 to 500 μm, more preferably 2 to 400 μm, further preferably 5 to 300 μm, particularly preferably 10 to 150 μm.

The particle diameter distribution (Dw/Dn) of the conductive particles P is preferably 1 to 10, more preferably 1 to 7, further preferably 1 to 5, particularly preferably 1 to 4.

Conductive particles P satisfying such conditions are used, whereby the resulting elastic anisotropically conductive films 20 become easy to deform under pressure, and sufficient electrical contact is achieved among the conductive particles P in the conductive parts 22 for connection in the elastic anisotropically conductive films.

No particular limitation is imposed on the form of the conductive particles P. However, they are preferably in the form of a sphere or star, or a mass of secondary particles obtained by aggregating these particles from the viewpoint of permitting these particles to be easily dispersed in the polymeric substance-forming material.

The content of water in the conductive particles P is preferably at most 5%, more preferably at most 3%, further preferably at most 2%, particularly preferably at most 1%. The use of conductive particles P satisfying such conditions can prevent or inhibit the molding material layer from causing bubbles therein upon the curing treatment of the molding material layer in the production process, which will be described subsequently.

Those obtained by treating surfaces of the conductive particles P with a coupling agent such as a silane coupling agent may be suitably used. By treating the surfaces of the conductive particles P with the coupling agent, the adhesion property of the conductive particles P to the elastic polymeric substance is improved, so that the resulting elastic anisotropically conductive films 20 become high in durability in repeated use.

The amount of the coupling agent used is suitably selected within limits not affecting the conductivity of the conductive particles P. However, it is preferably such an amount that a coating rate (proportion of an area coated with the coupling agent to the surface area of the conductive core particles) of the coupling agent on the surfaces of the conductive particles P amounts to at least 5%, more preferably 7 to 100%, further preferably 10 to 100%, particularly preferably 20 to 100%.

The proportion of the conductive particles P contained in the conductive parts 22 for connection in the functional part 21 is preferably 10 to 60%, more preferably 15 to 50% in terms of volume fraction. If this proportion is lower than 10%, conductive parts 22 for connection sufficiently low in electric resistance value may not be obtained in some cases. If the proportion exceeds 60% on the other hand, the resulting conductive parts 22 for connection are liable to be brittle, so that elasticity required of the conductive parts 22 for connection may not be achieved in some cases.

The proportion of the conductive particles P contained in the parts 25 to be supported varies according to the content of the conductive particles in the molding material for forming the elastic anisotropically conductive films 20. However, it is preferably equivalent to or more than the proportion of the conductive particles contained in the molding material in that the conductive particles P are surely prevented from being contained in excess in the conductive parts 22 for connection located most outside among the conductive parts 22 for connection in the elastic anisotropically conductive films 20. It is also preferably be at most 40% in terms of volume fraction in that parts 25 to be supported having sufficient strength are provided.

When the conductive part 26 for charge elimination is formed in the part 25 to be supported like this embodiment, the proportion of the conductive particles P contained in the conductive part 26 for charge elimination is preferably 3 to 40%, more preferably 3 to 30% in terms of volume fraction. If this proportion is lower than 3%, it may be difficult in some cases to sufficiently eliminate static electricity generated on the surfaces of the elastic anisotropically conductive films 20.

In the polymeric substance-forming material, as needed, may be contained a general inorganic filler such as silica powder, colloidal silica, aerogel silica or alumina. By containing such an inorganic filler, the thixotropic property of the resulting molding material is ensured, the viscosity thereof becomes high, the dispersion stability of the conductive particles P is improved, and moreover the strength of the elastic anisotropically conductive films 20 obtained by the curing treatment can be made high.

No particular limitation is imposed on the amount of such an inorganic filler used. However, the use in a too large amount is not preferred because the movement of the conductive particles P by the magnetic field is greatly inhibited in the production process, which will be described subsequently.

The anisotropically conductive connector described above may be produced, for example, in the following manner.

As illustrated in FIG. 5, a mold 60 for molding elastic anisotropically conductive films is provided.

The mold 60 is so constructed that a top force 61 and a bottom force 65 making a pair therewith are arranged so as to be opposed to each other.

In the top force 61, as illustrated on an enlarged scale in FIG. 6, ferromagnetic substance layers 63 are formed in accordance with a pattern antipodal to an arrangement pattern of conductive parts 22 for connection in each of elastic anisotropically conductive films 20 to be molded, and non-magnetic substance layers 64 are formed at other places than the ferromagnetic substance layers 63 on the lower surface of a base plate 62. A molding surface is formed by these ferromagnetic substance layers 63 and non-magnetic substance layers 64. Recesses 64a are formed in the molding surface of the top force 61 corresponding to the projected portions 24 in the elastic anisotropically conductive film 20 to be molded.

In the bottom force 65 on the other hand, ferromagnetic substance layers 67 are formed in accordance with the same pattern as the arrangement pattern of the conductive parts 22 for connection in each of the elastic anisotropically conductive films 20 to be molded, and non-magnetic substance layers 68 are formed at other portions than the ferromagnetic substance layers 67 on the upper surface of a base plate 66. A molding surface is formed by these ferromagnetic substance layers 67 and non-magnetic substance layers 68. Recesses 68a are formed in the molding surface of the bottom force 65 corresponding to the projected parts 24 in the elastic anisotropically conductive film 20 to be molded.

The respective base plates 62 and 66 in the top force 61 and bottom force 65 are preferably formed by a ferromagnetic substance. Specific examples of such a ferromagnetic substance include ferromagnetic metals such as iron, iron-nickel alloys, iron-cobalt alloys, nickel and cobalt. The base plates 62, 66 preferably have a thickness of 0.1 to 50 mm, and are preferably smooth at surfaces thereof and subjected to a chemical degreasing treatment or mechanical polishing treatment.

As a material for forming the ferromagnetic substance layers 63 and 67 in both top force 61 and bottom force 65, may be used a ferromagnetic metal such as iron, iron-nickel alloy, iron-cobalt alloy, nickel or cobalt. The ferromagnetic substance layers 63, 67 preferably have a thickness of at least 10 μm. When this thickness is at least 10 μm, a magnetic field having a sufficient intensity distribution can be applied to the molding material layers 20A. As a result, the conductive particles can be gathered at a high density at portions to become the conductive parts 22 for connection in the molding material layers 20A, and so conductive parts 22 for connection having good conductivity can be provided.

As a material for forming the non-magnetic substance layers 64 and 68 in both top force 61 and bottom force 65, may be used a non-magnetic metal such as copper, a polymeric substance having good heat resistance, or the like. However, a polymeric substance cured by radiation may preferably be used in that the non-magnetic substance layers 64, 68 can be easily formed by a technique of photolithography. As a material thereof, may be used, for example, a photoresist such as an acrylic type dry film resist, epoxy type liquid resist or polyimide type liquid resist.

A frame plate 10 composed of a magnetic metal, in which through-holes 11 have been formed corresponding to a pattern of electrode regions, in which electrodes to be inspected of integrated circuits in a wafer as an object of inspection have been formed, is first produced. As a means for forming the through-holes 11 in the frame plate 10, may be used, for example, an etching method or the like.

A molding material for molding the elastic anisotropically conductive films with conductive particles exhibiting magnetism dispersed in a polymeric substance-forming material, which will become an elastic polymeric substance by a curing treatment is then prepared. This molding material is applied on the molding surfaces of both top force 61 and bottom force 65 in the mold 60 in a necessary pattern by, for example, a screen printing method.

Specifically, as illustrated in FIG. 7, a mask 70 for printing is arranged on the molding surface (upper surface in FIG. 7) through a spacer 71 for printing, and the a necessary amount of the molding material 20B is coated on the molding surface of the top force 61 through openings of the mask 70 for printing and the spacer 7 for printing by a squeegee 72. The molding material is also coated on the molding surface of the bottom force 65 in the same manner as described above. In this process, the amount of the molding material coated on the molding surfaces of the top force 61 and bottom force 65 can be controlled according to the thickness of the mask 70 for printing and the spacer 71 for printing and the size of the openings thereof.

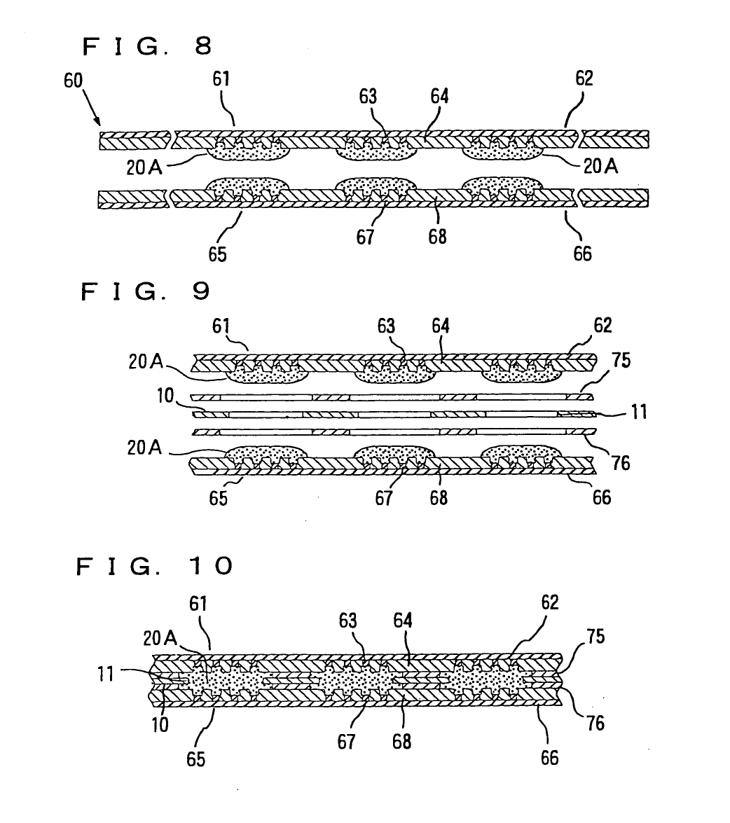

In such a manner, the molding material layers 20A of a necessary pattern are formed on the respective molding surfaces of the top force 61 and bottom force 65 as illustrated in FIG. 8.

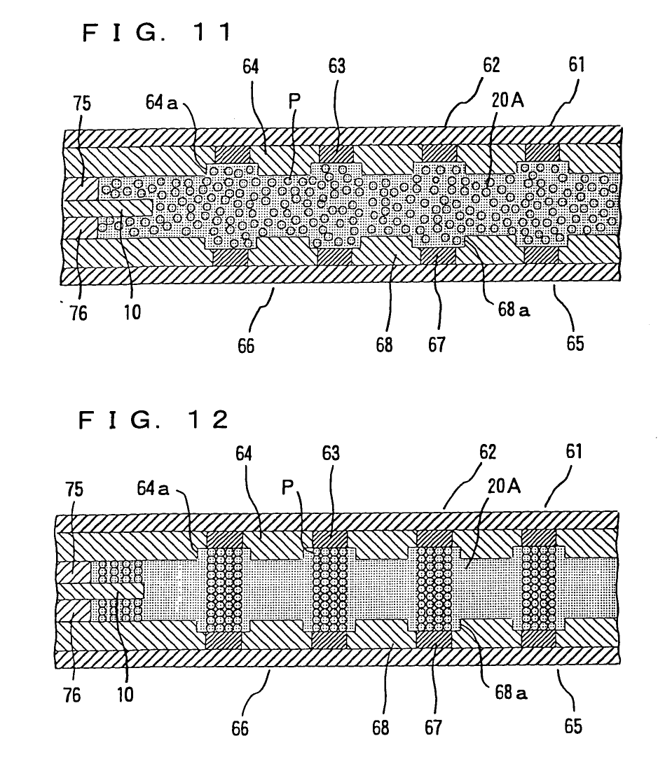

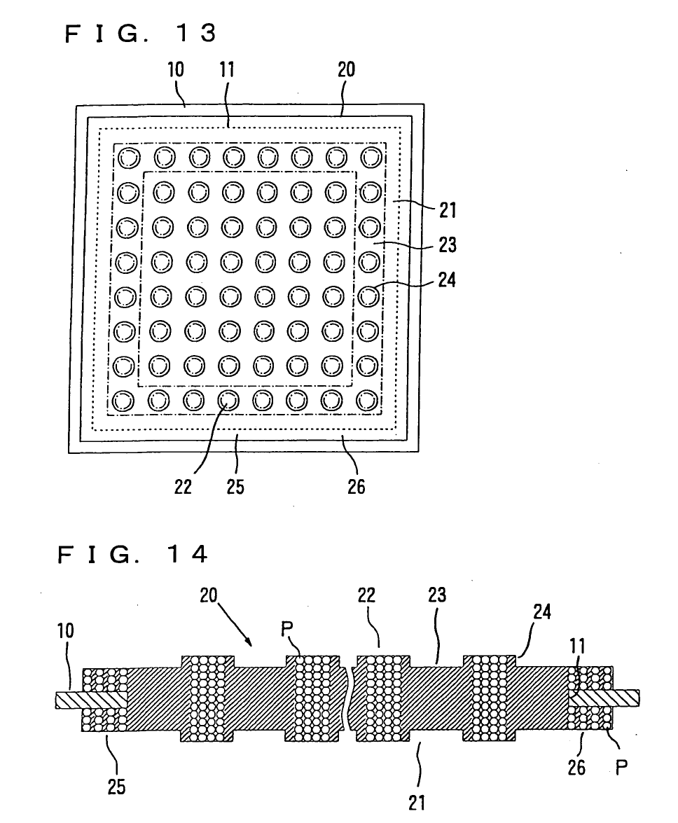

As illustrated in FIG. 9, the frame plate 10 is then arranged in alignment on the molding surface of the bottom force 65, on which the molding material layers 20A have been formed, through a spacer 76 for molding on the bottom force side, and on the frame plate 10, the top force 61, on which the molding material layers 20A have been formed, is arranged in alignment through a spacer 75 for molding on the top force side. These top and bottom forces are superimposed on each other, whereby molding material layers 20A of the intended form (form of the elastic anisotropically conductive films 20 to be formed) are formed between the top force 61 and the bottom force 65 as illustrated in FIG. 10. In each of these molding material layers 20A, the conductive particles P are contained in a state dispersed throughout in the molding material layer 20A as illustrated in FIG. 11.

In the process described above, when a total volume of the conductive particles P contained in the molding material layer 20A is regarded as V₁, and a total volume of the conductive parts 22 for connection in the elastic anisotropically conductive film 20 to be formed is regarded as V₂, a value of a ratio (V₁/V₂) is preferably 0.1 to 0.5. If the value of this ratio (V₁/V₂) is lower than 0.1, the amount of the conductive particles P gathered at the portions to become the conductive parts for connection in the molding material layer 20A tends to become too small, so that it may be difficult in some cases to provide any conductive part 22 for connection having sufficient conductivity and durability. If the value of this ratio (V₁/V₂) exceeds 0.5 on the other hand, the amount of the conductive particles P gathered at the portions to become the conductive parts for connection in the molding material layer 20A tends to become too great. As a result, it may be difficult in some cases to retain insulating property between adjacent conductive parts 22 for connection in the resulting elastic anisotropically conductive film 20.

A pair of, for example, electromagnets are then arranged on an upper surface of the base plate 62 in the top force 61 and a lower surface of the base plate 66 in the bottom force 65, and the electromagnets are operated, whereby a magnetic field having higher intensity at portions between the ferromagnetic substance layers 63 of the top force 61 and their corresponding ferromagnetic substance layers 67 of the bottom force 65 than surrounding regions thereof is formed because the top force 61 and the bottom force 65 have the ferromagnetic substance layers 63 and 67, respectively. As a result, in the molding material layer 20A, the conductive particles P dispersed in the molding material layer 20A are gathered at portions to become the conductive parts 22 for connection located between the ferromagnetic substance layers 63 of the top force 61 and their corresponding ferromagnetic substance layers 67 of the bottom force 65, and oriented so as to align in the thickness-wise direction of the molding material layer as illustrated in FIG. 12. In the above-described process, the frame plate 10 is composed of the magnetic metal, so that a magnetic field having higher intensity between each of the top plate 61 and the bottom plate 65, and the frame plate 10 than vicinities thereof is formed. As a result, the conductive particles P present above and below the frame plate 10 in the molding material layer 20A are not gathered between the ferromagnetic substance layer 63 of the top force 61 and the ferromagnetic substance layer 67 of the bottom force 65, but remain retained above and below the frame plate 10, and oriented so as to align in the thickness-wise direction.

In this state, the molding material layer 20A is subjected to a curing treatment, whereby the elastic anisotropically conductive film 20 composed of the functional part 21, in which a plurality of conductive parts 22 for connection containing the conductive particles P in the elastic polymeric substance in a state oriented so as to align in the thickness-wise direction are arranged in a state mutually insulated by the insulating part 23 composed of the elastic polymeric substance, in which the conductive particles P are not present at all or scarcely present, and the part 25 to be supported, which is continuously and integrally formed at a peripheral edge of the functional part 21, and in which the conductive part 26 for charge elimination with the conductive particles P contained in the elastic polymeric substance in a state oriented so as to align in the thickness-wise direction has been formed, is formed in a state that the part 25 to be supported has been fixed to the inner peripheral edge portion about the through-hole 11 in the frame plate 10, thereby producing the anisotropically conductive connector.

In the above-described process, the intensity of the magnetic field applied to the portions to become the conductive parts 22 for connection in the molding material layer 20A is preferably an intensity that it amounts to 0.1 to 2.5 T on the average of a magnetic flux density.

A magnetic flux density at the portion to become the part 25 to be supported in the molding material layer 20A is preferably 30 to 150%, more preferably 70 to 110% of the magnetic flux density at the portions to become the conductive parts 22 for connection. If the magnetic flux density at the portion to become the part 25 to be supported is too small, it may be difficult in some cases to retain the conductive particles P in the portion to become the part 25 to be supported. If the magnetic flux density at the portion to become the part 25 to be supported is too great on the other hand, a greater amount of the conductive particles P are gathered at the portion to become the part 25 to be supported, whereby the proportion of the conductive particles P gathered at the portions to become the conductive parts 22 for connection becomes low. As a result, good conductivity cannot be achieved in the resulting conductive parts for connection.

The curing treatment of the molding material layers 20A is suitably selected according to the material used. However, the treatment is generally conducted by a heat treatment. When the curing treatment of the molding material layers 20A is conducted by heating, it is only necessary to provide a heater in electromagnets. Specific heating temperature and heating time are suitably selected in view of the kinds of the polymeric substance-forming material forming the molding material layers 20A and the like, the time required for movement of the conductive particles P, and the like.

According to the anisotropically conductive connector described above, it is hard to be deformed and easy to handle because the part 25 to be supported is formed at the peripheral edge of the functional part 21 having the conductive parts 22 for connection, and this part 25 to be supported is fixed to the inner peripheral edge portion about the through-hole 11 in the frame plate 10. In addition, the positioning mark (for example, a hole or cut-out) is formed in, for example, the frame plate, whereby the positioning and the holding and fixing to a wafer as an object of inspection can be easily conducted upon an electrically connecting operation to the wafer.

Since the anisotropically conductive connector is obtained by subjecting the molding material layers 20A to the curing treatment, in the formation of the elastic anisotropically conductive films 20 of the anisotropically conductive connector, in a state that the conductive particles P present in the portions to become the parts 25 to be supported in the molding material layers 20A have been retained in those portions to become the parts 25 to be supported by applying a magnetic field to those portions, the conductive particles P present in the portions to become the parts 25 to be supported in the molding material layers 20A, i.e., portions located above and below the inner peripheral edge portions about the through-holes 11 in the frame plate 10 are not gathered at the portions to become the conductive parts 22 for connection. As a result, the conductive particles P are prevented from being contained in excess in the conductive parts 22 for connection located most outside among the conductive parts 22 for connection in the resulting elastic anisotropically conductive films 20. Accordingly, there is no need of reducing the content of the conductive particles P in the molding material layers 20A, so that good conductivity is achieved with certainty in all the conductive parts 22 for connection in the elastic anisotropically conductive films 20, and moreover insulating property between adjacent conductive parts 22 for connection can be achieved with certainty.

Since the conductive part 26 for charge elimination is formed in the part 25 to be supported in each of the elastic anisotropically conductive films 20, the conductive part 26 for charge elimination is electrically connected to the ground through the frame plate 10, whereby static electricity generated on the surface of the elastic anisotropically conductive film 20 is eliminated through the conductive part 26 for charge elimination. As a result, it can be prevented or inhibited that electric charges are accumulated on the surface of the elastic anisotropically conductive film 20, so that adverse influence by static electricity can be excluded.

Specifically, the static electricity generated on the surface of the elastic anisotropically conductive films 20 by repeatedly conducting both pressurizing operation and separating operation to the wafer as the object of inspection can be eliminated through the conductive parts 26 for charge elimination. As a result, electric charges can be sufficiently inhibited from being accumulated on the surfaces of the elastic anisotropically conductive films 20, and static electricity of high potential can be prevented from being generated. Accordingly, adverse influence by static electricity can be excluded and electrical inspection of the wafer can be conducted with high efficiency and high safety.

Even if the surfaces of the elastic anisotropically conductive films 20 are charged with static electricity by repeatedly conducting the pressurizing operation and separating operation, and the static electricity is discharged, the discharge is caused at the conductive parts 26 for charge elimination. As a result, adverse influence imposed on the conductive parts 22 for connection and the like can be excluded and the electrical inspection of the wafer can be conducted with high safety.

Since thermal expansion in a plane direction of elastic anisotropically conductive film 20 is restrained by the frame plate 10, a good electrically connected state to the wafer can be stably retained by using a material having a low coefficient of linear thermal expansion as that for forming the frame plate 10 even when it is subjected to thermal hysteresis by temperature change.

Further, since a plurality of the through-holes 11 are formed corresponding to an electrode region, in which the electrodes to be inspected of integrated circuits in the wafer as the object of inspection have been formed in the frame plate 10, each of the elastic anisotropically conductive film 20 arranged in the respective through-holes 11 may be small in area. Therefore, the absolute quantity of thermal expansion in the plane direction of each of the elastic anisotropically conductive films 20 is thus a little even when it is subjected to the thermal hysteresis, thereby a good electrically connected state can also be stably retained to a wafer of large-area.

FIG. 13 is a plan view illustrating another exemplary anisotropically conductive connector according to the present invention, and FIG. 14 is a cross-sectional view illustrating, on an enlarged scale, an elastic anisotropically conductive film in the anisotropically conductive connector shown in FIG. 13.

This anisotropically conductive connector has a frame plate 10 in a frame form as a whole, in which a through-hole 11 extending in a thickness-wise direction of the frame plate has been formed at a center, and an elastic anisotropically conductive film 20 having conductivity in a thickness-wise direction thereof is arranged in the through-hole 11 in this frame plate 10 in a state supported by an inner peripheral edge portion about the through-hole 11 in the frame plate 10.

As illustrated in FIG. 3, the elastic anisotropically conductive film 20, a base material of which is composed of an elastic polymeric substance, has a functional part 21 composed of a plurality of conductive parts 22 for connection arranged in accordance with a pattern corresponding to a pattern of electrodes of a circuit device to be connected and each extending in the thickness-wise direction and insulating parts 23 formed around the respective conductive parts 22 for connection and mutually insulating these conductive parts 22 for connection. The functional part 21 is arranged so as to be located in the through-hole 11 in the frame plate 10. A part 25 to be supported, which is fixed to and supported by an inner peripheral edge portion about the through-hole 11 in the frame plate 10, is integrally continuously formed at a peripheral edge of the functional part 21. More specifically, the part 25 to be supported in this embodiment is shaped in a forked form and fixed and supported in a closely contacted state so as to grasp the inner peripheral edge portion about the through-hole 11 in the frame plate 10. In the part 25 to be supported, conductive particles P are contained in a state oriented so as to align in the thickness-wise direction, whereby a conductive part 26 for charge elimination, in which a conductive path is formed in a thickness-wise direction of the part by the conductive particles P, is formed over the part 25 to be supported.

Materials for forming the frame plate 10 and elastic anisotropically conductive film 20 are the same as those in the anisotropically conductive connector shown in FIGS. 1 to 4.

Such an anisotropically conductive connector may be used as a connector for achieving electrical connection between circuit devices of, for example, a printed circuit board such as a single-sided printed circuit board, double-sided printed circuit board or multi-layer printed circuit board and an electronic part, such as a surface-packaging semiconductor integrated circuit device such as a semiconductor chip, BGA or CSP, or liquid crystal display device, or as a connector for achieving electrical connection between a circuit device of any of the above-described printed circuit boards and electronic parts and a tester by causing it to intervene between them in electrical inspection for such a circuit device.

According to the anisotropically conductive connector described above, it is hard to be deformed and easy to handle because the part 25 to be supported is formed at the peripheral edge of the functional part 21 having the conductive parts 22 for connection, and this part 25 to be supported is fixed to the inner peripheral edge portion about the through-hole 11 in the frame plate 10. In addition, the positioning mark (for example, a hole or cut-out) is formed in, for example, the frame plate, whereby the positioning and the holding and fixing to a circuit device to be connected can be easily conducted upon an electrically connecting operation to the circuit device.

Since the above-described anisotropically conductive connector is obtained by subjecting the molding material layer to the curing treatment, in the formation of the elastic anisotropically conductive films 20 of the anisotropically conductive connector, in a state that the conductive particles P present in the portion to become the part 25 to be supported in the molding material layer have been retained in this portion to become the part 25 to be supported by applying a magnetic field to this portion, the conductive particles P present in the portion to become the part 25 to be supported in the molding material layer, i.e., a portion located above and below the inner peripheral edge portion about the through-hole 11 in the frame plate 10 are not gathered at the portions to become the conductive parts 22 for connection. As a result, the conductive particles P are prevented from being contained in excess in the conductive parts 22 (conductive parts 22 for connection surrounded by an alternate long and short dash line in FIG. 13) for connection located most outside among the conductive parts 22 for connection in the resulting elastic anisotropically conductive film 20. Accordingly, there is no need of reducing the content of the conductive particles P in the molding material layer, so that good conductivity is achieved with certainty in all the conductive parts 22 for connection in the elastic anisotropically conductive film 20, and moreover insulating property between adjacent conductive parts 22 for connection can be achieved with certainty to effectively use all the conductive parts 22 for connection.

Since the conductive part 26 for charge elimination is formed in the part 25 to be supported in the elastic anisotropically conductive film 20, the conductive part 26 for charge elimination is electrically connected to the ground through the frame plate 10, whereby static electricity generated on the surface of the elastic anisotropically conductive film 20 is eliminated through the conductive part 26 for charge elimination. As a result, it can be prevented or inhibited that electric charges are accumulated on the surface of the elastic anisotropically conductive film 20, so that static electricity of high potential can be prevented from being generated, or discharge occurs in the conductive part 26 for charge elimination even when the surface is charged with static electricity. Accordingly, various adverse influences by static electricity can be excluded.

Since thermal expansion in a plane direction of the elastic anisotropically conductive film 20 is restrained by the frame plate 10, a good electrically connected state to the circuit device to be connected can be stably retained by using a material having a low coefficient of linear thermal expansion as that for forming the frame plate 10 even when it is subjected to thermal hysteresis by temperature change.

[Electrical Inspection Apparatus for Circuit Device]

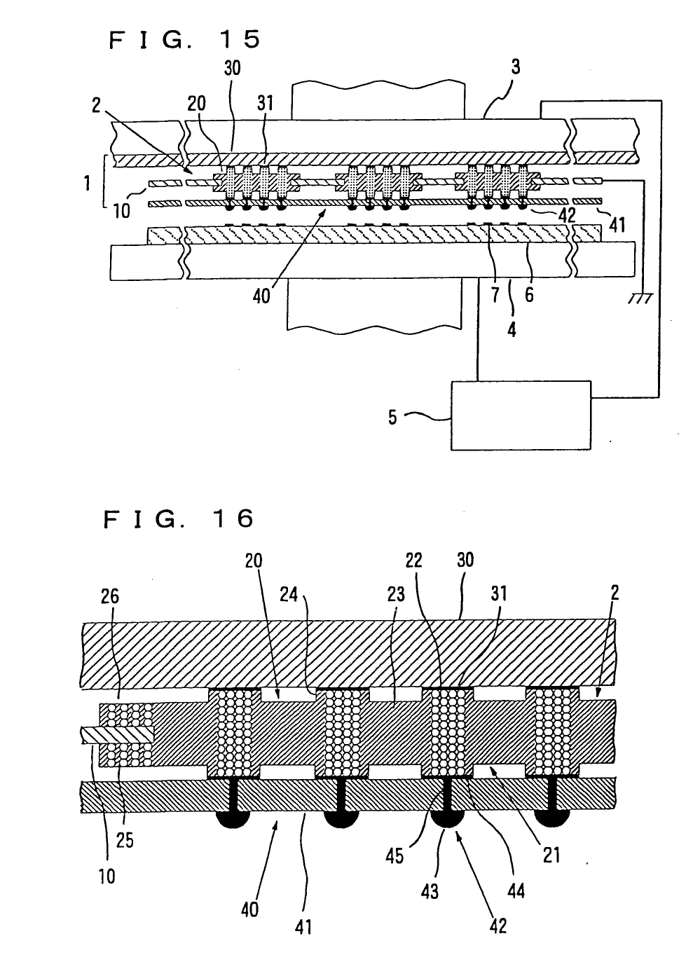

FIG. 15 is a cross-sectional view schematically illustrating the construction of an exemplary electrical inspection apparatus for circuit devices according to the present invention. The electrical inspection apparatus for circuit devices serves to perform electrical inspection of each of a plurality of integrated circuits formed on a wafer in a state of the wafer.

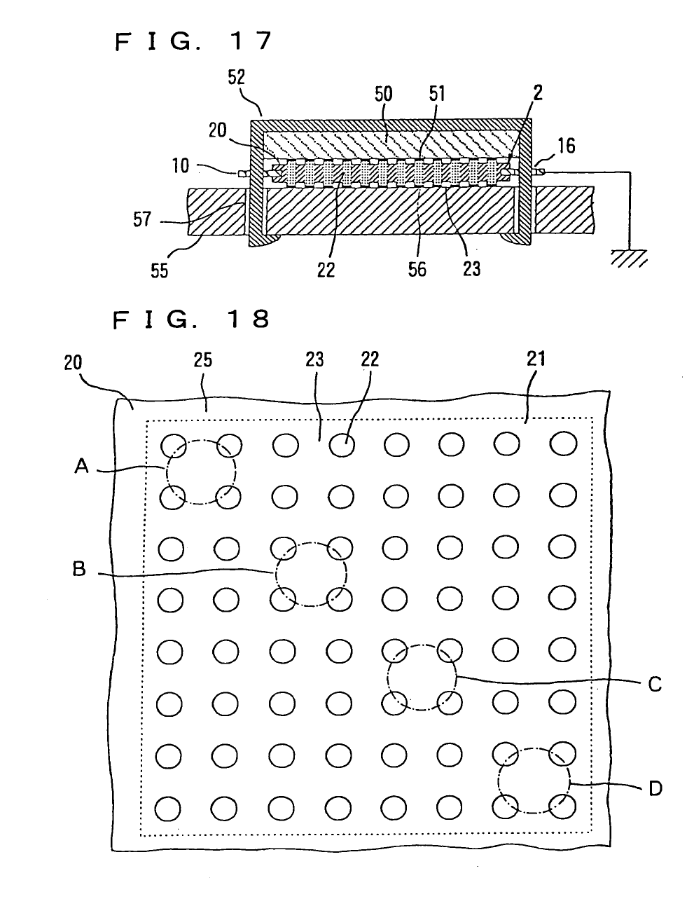

The electrical inspection apparatus for circuit devices shown in FIG. 15 has a probe member 1 for conducting electrical connection of each of electrodes 7 to be inspected of a wafer 6 as an object of inspection to a tester. As also illustrated on an enlarged scale in FIG. 16, the probe member 1 has a circuit board 30 for inspection, on a front surface (lower surface in FIG. 15) of which a plurality of inspection electrodes 31 have been formed in accordance with a pattern corresponding to a pattern of the electrodes 7 to be inspected of the wafer 6 as the object of inspection. On the front surface of the circuit board 30 for inspection, is provided the anisotropically conductive connector 2 of the structure illustrated in FIGS. 1 to 4 in such a manner that each of the conductive parts 22 for connection in the elastic anisotropically conductive films 20 of the connector are opposed to and brought into contact with the respective inspection electrodes 31 of the circuit board 30 for inspection. The anisotropically conductive connector 2 is grounded by a proper means.

On a front surface (lower surface in FIG. 15) of the anisotropically conductive connector 2, is provided a sheet-like connector 40, in which a plurality of electrode structures 42 have been arranged in an insulating sheet 41 in accordance with the pattern corresponding to the pattern of the electrodes 7 to be inspected of the wafer 6 as the object of inspection, in such a manner that each of the electrode structures 42 are opposed to and brought into contact with the respective conductive parts 22 for connection in the elastic anisotropically conductive films 20 of the anisotropically conductive connector 2.

On a back surface (upper surface in FIG. 15) of the circuit board 30 for inspection in the probe member 1, is provided a pressing plate 3 for pressurizing the probe member 1 downward. A wafer-mounting table 4, on which the wafer 6 as the object of inspection is mounted, is provided below the probe member 1. The pressing plate 3 and the wafer-mounting table 4 are connected to a heater 5.

The sheet-like connector 40 in the probe member 1 will be described specifically. The sheet-like connector 40 has a flexible insulating sheet 41, and in this insulating sheet 41, a plurality of electrode structures 42 extending in a thickness-wise direction of the insulating sheet 41 and composed of a metal are arranged with a space to each other in a plane direction of the insulating sheet 41 in accordance with the pattern corresponding to the pattern of the electrodes 7 to be inspected of the wafer 6 as the object of inspection.

Each of the electrode structures 42 is formed by integrally connecting a projected front-surface electrode part 43 exposed from a front surface (lower surface in FIG. 16) of the insulating sheet 41 and a plate-like back-surface electrode part 44 exposed from a back surface of the insulating sheet 41 to each other by a short circuit part 45 extending through in the thickness-wise direction of the insulating sheet 41.

No particular limitation is imposed on the insulating sheet 41 so far as it has insulating property and is flexible. For example, a resin sheet formed of a polyimide resin, liquid crystal polymer, polyester, fluororesin or the like, or a sheet obtained by impregnating a cloth woven by fibers with any of the above-described resins may be used.

No particular limitation is also imposed on the thickness of the insulating sheet 41 so far as such an insulating sheet 41 is flexible. However, it is preferably 10 to 50 μm, more preferably 10 to 25 μm.

As a metal for forming the electrode structures 42, may be used nickel, copper, gold, silver, palladium, iron or the like. The electrode structures 42 may be any of those formed of a simple metal, those formed of an alloy of at least two metals and those obtained by laminating at least two metals as a whole.

On the surfaces of the front-surface electrode part 43 and back-surface electrode part 44 in the electrode structure 42, a film of a chemically stable metal having high conductivity, such as gold, silver or palladium is preferably formed in that oxidation of the electrode parts is prevented, and electrode parts small in contact resistance are provided.

The projected height of the front-surface part 43 in the electrode structure 42 is preferably 15 to 50 μm, more preferably 15 to 30 μm in that stable electrical connection to the electrode 7 to be inspected of the wafer 6 can be achieved. The diameter of the front-surface electrode part 43 is preset according to the size and pitch of the electrodes to be inspected of the wafer 6 and is, for example, 30 to 80 μm, preferably 30 to 50 μm.

The diameter of the back-surface electrode part 44 in the electrode structure 42 is only required to be greater than the diameter of the short circuit part 45 and smaller than the arrangement pitch of the electrode structures 42 and is preferably great as much as possible. Stable electrical connection to the conductive part 22 for connection in the elastic anisotropically conductive film 20 of the anisotropically conductive connector 2 can also be thereby achieved with certainty. The thickness of the back-surface part 44 is preferably 20 to 50 μm, more preferably 35 to 50 μm in that sufficiently high strength and excellent repetitive durability are achieved.

The diameter of the short circuit part 45 in the electrode structure 42 is preferably 30 to 80 μm, more preferably 30 to 50 μm in that sufficiently high strength is achieved.

The sheet-like connector 40 can be produced, for example, in the following manner.

More specifically, a laminate material obtained by laminating a metal layer on an insulating sheet 41 is provided, and a plurality of through-holes extending through in a thickness-wise direction of the insulating sheet 41 are formed in the insulating sheet 41 of the laminate material in accordance with a pattern corresponding to a pattern of electrode structures 42 to be formed by laser machining, dry etch machining or the like. This laminate material is then subjected to photolithography and plating treatment, whereby short circuit parts 45 integrally joined to the metal layer are formed in the through-holes in the insulating sheet 41, and at the same time, projected front-surface electrode parts 43 integrally joined to the respective short circuit parts 45 are formed on the front surface of the insulating sheet 41. Thereafter, the metal layer of the laminate material is subjected to a photo-etching treatment to remove a part thereof, thereby forming back-surface electrode parts 44 to form the electrode structures 42 so as to provide the sheet-like connector 40.

In such an electrical inspection apparatus, a wafer 6 as an object of inspection is mounted on the wafer-mounting table 4, and the probe member 1 is then pressurized downward by the pressing plate 3, whereby the respective front-surface electrode parts 43 in the electrode structures 42 of the sheet-like connector 40 thereof are brought into contact with their corresponding electrodes 7 to be inspected of the wafer 6, and further the respective electrodes 7 to be inspected of the wafer 6 are pressurized by the front-surface electrodes parts 43. In this state, the conductive parts 22 for connection in the elastic anisotropically conductive films 20 of the anisotropically conductive connector 2 are respectively held and pressurized by the inspection electrodes 31 of the circuit board 30 for inspection and the front-surface electrode parts 43 in the electrode structures 42 of the sheet-like connector 40 and compressed in the thickness-wise direction of the elastic anisotropically conductive films 20, whereby conductive paths are formed in the respective conductive parts 22 for connection in the thickness-wise direction thereof. As a result, electrical connection between the electrodes 7 to be inspected of the wafer 6 and the inspection electrodes 31 of the circuit board 30 for inspection is achieved. Thereafter, the wafer 6 is heated to a prescribed temperature by the heater 5 through the wafer-mounting table 4 and pressing plate 3. In this state, necessary electrical inspection is curried out on each of a plurality of integrated circuits in the wafer 6.

According to such an electrical inspection apparatus, electrical connection to the electrodes 7 to be inspected of the wafer 6 as the object of inspection is achieved through the probe member 1 having the above-described anisotropically conductive connector 2. Therefore, positioning, and holding and fixing to the wafer can be conducted with ease even when the pitch of the electrodes 7 to be inspected is small. In addition, high reliability on connection to each electrode to be inspected is achieved.

Since thermal expansion in a plane direction of the elastic anisotropically conductive film 20 is restrained by the frame plate 10 in the anisotropical conductive connector 2, a good electrically connected state to the wafer can be stably retained by using a material having a low coefficient of linear thermal expansion as that for forming the frame plate 10 even when it is subjected to thermal hysteresis by temperature change.

Further, since a plurality of the through-holes are formed corresponding to an electrode region, in which the electrodes 7 to be inspected of integrated circuits in the wafer 6 as the object of inspection have been formed in the frame plate 10 in the anisotropically conductive connector 2, the elastic anisotropically conductive film 20 arranged in each of the through-holes may be small in area. Therefore the absolute quantity of thermal expansion in the plane direction of each of the elastic anisotropically conductive films 20 is a little even when it is subjected to the thermal hysteresis, thereby a good electrically connected state to the wafer 6 can also be stably retained even when the wafer 6 has a large area.

Since the conductive part 26 for charge elimination in the elastic anisotropically conductive film 20 of the anisotropically conductive connector 2 is electrically connected to the ground through the frame plate 10, static electricity generated on the surface of the elastic anisotropically conductive film 20 in the anisotropically conductive connector 2 by repeatedly conducting the pressurizing operation and separating operation of the probe member 1 to the wafer 6 can be eliminated through the conductive parts 26 for charge elimination. As a result, electric charges can be sufficiently inhibited from being accumulated on the surface of the elastic anisotropically conductive film 20, and static electricity of high potential can be prevented from being generated. Accordingly, adverse influence by static electricity can be excluded, and electrical inspection of the wafer can be conducted with high efficiency and high safety.

Even if the surface of the elastic anisotropically conductive film 20 in the anisotropically conductive connector 2 is charged with static electricity by repeatedly conducting the pressurizing operation and separating operation of the probe member 1, and the static electricity is discharged, the discharge is caused at the conductive part 26 for charge elimination. As a result, adverse influence imposed on the conductive parts 22 for connection in the elastic anisotropically conductive film 20, the circuit board 10 for inspection, the wafer 6 as the object of inspection, and the like can be excluded, and the electrical inspection of the wafer 6 can be conducted with high safety.

[Conductive Connection Structure]

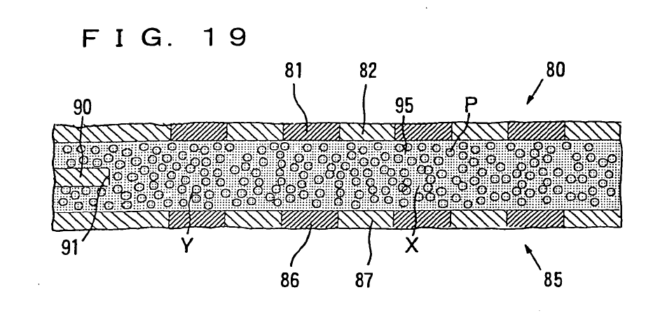

FIG. 17 is a cross-sectional view illustrating the construction of an exemplary conductive connection structure according to the present invention. In this conductive connection structure, an anisotropically conductive connector 2 of, for example, the construction shown in FIGS. 11 and 12 is arranged on a circuit board 55 in such a manner that the conductive parts 22 for connection in the elastic anisotropically conductive films 20 thereof are located on electrodes 56 of the circuit board 55. A frame plate 10 in the anisotropically conductive connector 2 is grounded by a proper means. An electronic part 50 is arranged on the anisotropically conductive sheet 2 in such a manner that electrodes 51 thereof are located on the conductive parts 22 for connection in the elastic anisotropically conductive films 20 of the anisotropically conductive connector 2. The electronic part 50 and anisotropically conductive connector 2 is fixed to the circuit board 55 by a fixing member 52 in a state that the conductive parts 22 for connection in the elastic anisotropically conductive films 20 have been held and pressurized by the electrodes 51 of the electronic part 50 and the electrodes 56 of the circuit board 55, and the electrodes 51 of the electronic part 50 are electrically connected to the electrodes 56 of the circuit board 55 through the conductive parts 22 for connection in the elastic anisotropically conductive films 20. Reference numerals 16 and 57 designate a positioning hole formed in the frame plate 10 of the anisotropically conductive connector 2 and a positioning hole formed in the circuit board 55, respectively. A leg of the fixing member 52 is inserted through each of the positioning holes 16 and 57 in the frame plate 10 and circuit board 55.

No particular limitation is imposed on the electronic part 50 so far as it is of a surface-packaging type, and any of various electronic parts may be used. Examples thereof include active devices composed of a semiconductor device such as a transistor, diode, IC chip, LSI chip or a package thereof, or MCM (multi chip module), and passive devices such as resistors, capacitors and quartz oscillators.

As the circuit board 55, may be used those of various structures, such as a single-sided printed circuit board, double-sided printed circuit board and multi-layer printed circuit board. The circuit board 55 may be any of a flexible board, rigid board and a flexible-rigid board composed of a combination thereof.

When a flexible board is used as the circuit board 55, polyimide, polyamide, polyester, polysulfone or the like may be used as a material for forming the flexible board.

When a rigid board is used as the circuit board 55, a composite resin material such as a glass fiber-reinforced epoxy resin, glass fiber-reinforced phenol resin, glass fiber-reinforced polyimide resin or glass fiber-reinforced bismaleimide triazine resin, or a ceramic material such as silicon dioxide or alumina may be used as a material for forming the rigid board.

Examples of a material for the electrodes 51 of the electronic part 50 and the electrodes 56 of the circuit board 55 include gold, silver, copper, nickel, palladium, carbon, aluminum and ITO.

The thickness of each of the electrodes 51 of the electronic part 50 and the electrodes 56 of the circuit board 55 is preferably 0.1 to 100 μm.

The width of each of the electrodes 51 of the electronic part 50 and the electrodes 56 of the circuit board 55 is preferably 1 to 500 μm.

According to such a conductive connection structure as described above, the electronic part 50 and circuit board 55 are electrically connected to each other through the anisotropically conductive connector 2 described above, so that good electrical connection between each of the electrodes 51 of the electronic part 50 and each of the electrodes 56, corresponding to the respective electrode 51 of the circuit board 55 is achieved with certainty, and more over insulating property between adjacent electrodes is achieved with certainty. Accordingly, high reliability on connection is achieved.

Further, since the conductive parts 26 for charge elimination in the elastic anisotropically conductive films 20 of the anisotropically conductive connector 2 are electrically connected to the ground through the frame plate 10, static electricity generated on the surface of the elastic anisotropically conductive films 20 is eliminated through the parts 26 for charge elimination. As a result, it can be prevented or inhibited that electric charges are accumulated on the surfaces of the elastic anisotropically conductive films 20, so that an erroneous operation of the electronic part 50 due to the static electricity and adverse influence such as troubles of the electronic part 50 and circuit board 55 due to the static electricity can be excluded.

[Other Embodiments]

The present invention is not limited to the above-described embodiments, and various modifications may be added thereto.

For example, in the anisotropically conductive connector, the projected parts 24 in each elastic anisotropically conductive film 20 are not essential, and one or both surfaces may be flat, or a recess may be formed.

When the frame plate 10 has a plurality of the through-holes 11, part or all of the elastic anisotropically conductive films 20 arranged in these through-holes 11 may be those in which one conductive part 22 for connection is formed.

When a non-magnetic substance is used as a base material of the frame plate 10 in the production of the anisotropically conductive connector, as a means for applying the magnetic field to the portion to become the part 25 to be supported in each molding material layer 20A, may be utilized a means of plating the inner peripheral edge portion about the through-hole 11 in the frame plate 10 with a magnetic substance or coating it with a magnetic paint to apply a magnetic field thereto, or a means of forming a ferromagnetic substance layer in the mold 60 corresponding to the part 25 to be supported of the elastic anisotropically conductive film 20 to apply a magnetic field thereto.

In the electrical inspection apparatus of the circuit board, the circuit board as the object of inspection is not limited to the wafer, on which the integrated circuits have been formed, and the electrical inspection apparatus may also be applied to an electrical inspection apparatus for printed circuit boards such as single-sided printed circuit boards, double-sided printed circuit boards and multi-layer printed circuit boards and other surface-packaging electronic parts such as semiconductor chips, BGA and CSP.

The sheet-like connector 40 is not essential, and the elastic anisotropically conductive films 20 in the anisotropically conductive connector 2 may be brought into contact with a circuit device as an object of inspection to achieve electrical connection.

The present invention will hereinafter be described specifically by the following examples. However, the present invention is not limited to these examples.

### EXAMPLE 1

A frame plate, a mold for molding elastic anisotropically conductive films and a spacer for molding were produced in accordance with the following respective conditions.

[Frame Plate (10)]

Material:

Covar (saturation magnetization: 1.4 Wb/m²), thickness: 0.4 mm, size of through-hole (11): 16 mm×16 mm (sectional area S₁ in the plane direction: 2.56 cm²).

[Mold (60)]

Base Plates (62, 66):

Material: iron, thickness: 6 mm;

Ferromagnetic Substance Layers (63, 67):

Material: nickel, size: diameter: 1 mm (circular form), thickness: 0.1 mm, arrangement pitch (center distance): 2 mm, number of ferromagnetic layers: 64 layers (8×8 layers);

Non-Magnetic Substance Layers (64, 68):

Material: that obtained by subjecting a dry film resist to a curing treatment, size of recesses (64a, 68a): diameter: 1.1 mm (circular form), depth: 0.4 mm, thickness of other portions than the recess: 0.5 mm (thickness of the recess: 0.1 mm). [Spacers (75, 76) for Molding]

Material: SUS304, thickness: 0.4 mm, size of opening: 19 mm×19 mm.

One hundred parts by weight of conductive particles having an average particle diameter of 20 μm were added to and mixed with 100 parts by weight of addition type liquid silicone rubber. Thereafter, the resultant mixture was subjected to a defoaming treatment by pressure reduction, thereby preparing a molding material for molding an elastic anisotropically conductive film. In the above-described process, as the conductive particles, those (average amount coated: 20% by weight of the weight of core particles) obtained by plating the core particles formed of nickel with gold were used.

The molding material prepared was applied to the surfaces of the top force (61) and bottom force (65) of the mold (60) by screen printing, thereby forming a molding material layer (20A), and the frame plate (10) described above was superimposed in alignment on the molding surface of the bottom force (65) through the spacer (76) for molding on the side of the bottom force. Further, the top force (61) was superimposed in alignment on the frame plate (10) through the spacer (75) for molding on the side of the top force, thereby forming a molding material layer (20A) of the intended form between the top force (61) and the bottom force (65). The total volume V₁ of the conductive particles contained in the molding material layer (20A) was 0.04 cm³.

The molding material layer (20A) was subjected to a curing treatment under conditions of 100° C. and 1 hour while applying a magnetic field to portions (portions to become conductive parts (22) for connection) located between the corresponding ferromagnetic substance layers (62, 67) in the thickness-wise direction by electromagnets so as to give a magnetic flux density of 2 T, thereby forming an elastic anisotropically conductive film (20) having a width of 22 mm in vertical and lateral directions to produce an anisotropically conductive connector according to the present invention. In the above-described process, a magnetic flux density at portions to become a part (25) to be supported in the molding material layer (20A) was 2.1 T (105% of the magnetic flux density at the portions to become parts (22) for connection).

The elastic anisotropically conductive film (20) in the anisotropically conductive connector thus obtained was such that 64 conductive parts (22) for connection in total in the form of a circle, which had a diameter of 1 mm and a thickness of 2.0 mm, were arranged at a pitch of 2 mm (total sectional area S₂ in the plane direction of the conductive parts (22) for connection: 0.5 cm², value of a ratio (S₂/S₁): 0.2, total volume V₂ of the conductive part(s) (22) for connection: 0.1 cm³, value of a ratio (V₁/V₂): 0.4), the shortest clearance between the inner peripheral edge surface of the through-hole (11) in the frame plate (10) and the conductive part (22) for connection was 0.5 mm (0.25 times as much as the thickness of the conductive part (22) for connection), the thickness of the insulating parts (23) was 1.2 mm, the thickness (thickness of one of the forked portion) of the part (25) to be supported was 0.4 mm, and the height of the projected portions (24) was 0.4 mm.

The proportions of the conductive particles contained in the conductive parts (22) for connection and the part (25) to be supported in the elastic anisotropically conductive film (20) were investigated. As a result, the contents were 35% in terms of a volume fraction for the conductive parts (22) for connection and 10% for the part (25) to be supported.

The volume resistivity of the part (25) to be supported in the thickness-wise direction thereof was measured in a state that the part (25) to be supported was compressed by 3% in the thickness-wise direction thereof. As a result, the resistivity was 3×10⁻¹ Ω·m, and so it was found that the conductive part (26) for charge elimination was formed over the whole part (25) to be supported.

### EXAMPLES 2 TO 4

Respective anisotropically conductive connectors were produced in the same manner as in Example 1 except that frame plates (10), molds (60) and spacers (75, 76) for molding were produced in accordance with their corresponding conditions shown in Table 1, and these frame plates (10), molds (60) and spacers (75, 76) for molding were used to form each elastic anisotropically conductive film (20). The total volume of the conductive particles in the molding material layer, the size of the elastic anisotropically conductive film (20), and the like are shown in Table 2.

The proportions of the conductive particles contained in the conductive parts (22) for connection and the part (25) to be supported in the elastic anisotropically conductive film (20) of each of the anisotropically conductive connectors thus obtained were investigated. As a result, the contents were 35% in terms of a volume fraction for the conductive parts (22) for connection and 10% for the part (25) to be supported.

The volume resistivity of the part (25) to be supported in the thickness-wise direction thereof was measured in a state that the part (25) to be supported was compressed by 3% in the thickness-wise direction thereof. As a result, the resistivity was 3×10⁻¹ Ω·m, and so it was found that the conductive part (26) for charge elimination was formed over the whole part (25) to be supported.

TABLE 1

| | | | Example 1 | Example 2 | Example 3 | Example 4 |
|---|---|---|---|---|---|---|
| Frame | Material | | Covar | Covar | Covar | Covar |
| plate | Thickness (mm) | | 0.4 | 0.2 | 0.1 | 0.04 |
| | Through-hole | Vertical width (mm) | 16 | 8 | 4 | 1.6 |
| | | Lateral width (mm) | 16 | 8 | 4 | 1.6 |
| | | Sectional | 2.6 | 0.64 | 0.16 | 0.026 |
| | | area S₁ (cm²) | | | | |

| | | | | | | |
|---|---|---|---|---|---|---|
| Mold | Base plate | Material | Iron | Iron | Iron | Iron |
| (Top force | | Thickness (mm) | 6 | 6 | 6 | 6 |

| and bottom | Ferromagnetic | Material | | Nickel | Nickel | Nickel | Nickel |
|---|---|---|---|---|---|---|---|
| force) | substance | Diameter (mm) | | 1 | 0.5 | 0.25 | 0.1 |
| | layer | Thickness (mm) | | 0.1 | 0.1 | 0.1 | 0.1 |
| | | Arrangement pitch(mm) | | 2 | 1 | 0.5 | 0.2 |
| | | Number of the layers | | 8 × 8 | 8 × 8 | 8 × 8 | 8 × 8 |
| | | (Count × Count) | | | | | |
| | Non-magnetic | Material | | Material is obtained by | Material is obtained by | Material is obtained by | Material is obtained |
| | substance | | | subjecting a dry film | subjecting a dry film | subjecting a dry film | by subjecting a |
| | layer | | | resist to a curing | resist to a curing | resist to a curing | dry film resist |
| | | | | treatment | treatment | treatment | to a curing |
| | | | | | | | treatment |
| | | Recess | Diameter | 1.1 | 0.55 | 0.275 | 0.11 |
| | | | (mm) | | | | |
| | | | Depth (mm) | 0.4 | 0.2 | 0.1 | 0.04 |

| | | | | |
|---|---|---|---|---|
| Thickness (mm) | 0.5 | 0.3 | 0.2 | 0.14 |

| Spacer for | Material | | SUS304 | SUS304 | SUS304 | SUS304 |
|---|---|---|---|---|---|---|
| molding | Thickness (mm) | | 0.4 | 0.2 | 0.1 | 0.04 |
| (On the | Opening | Vertical width (mm) | 19 | 10 | 5 | 2 |
| side of | | Lateral width (mm) | 19 | 10 | 5 | 2 |
| top force | | | | | | |
| and | | | | | | |
| bottom | | | | | | |
| force) | | | | | | |

TABLE 2

| | | | Example 1 | Example 2 | Example 3 | Example 4 |
|---|---|---|---|---|---|---|
| Total volume of the conductive perticles | | | 4 × 10⁻² | 5 × 10⁻³ | 7 × 10⁻⁴ | 4 × 10⁻⁵ |
| in the molding material layer | | | | | | |
| V₁ (cm³) | | | | | | |
| Elastic | Vertical width (mm) | | 19 | 10 | 5 | 2 |
| anisotropically | Lateral width (mm) | | 19 | 10 | 5 | 2 |
| coductive | Conductive | Diameter (mm) | 1 | 0.5 | 0.25 | 0.1 |
| film | parts for | Thickness | 2 | 1 | 0.5 | 0.2 |
| | connection | Number of the | 8 × 8 | 8 × 8 | 8 × 8 | 8 × 8 |
| | | conductive parts | | | | |
| | | (count × count) | | | | |
| | | Total sectional | 0.5 | 0.13 | 0.031 | 0.005 |
| | | area S₂(cm²) | | | | |
| | | Total volume V₂(cm³) | 0.1 | 0.013 | 0.0016 | 0.0001 |
| | | Arrangement pitch (mm) | 2 | 1 | 0.5 | 0.2 |

| | | | | |
|---|---|---|---|---|
| Thickness of | 1.2 | 0.6 | 0.3 | 0.12 |
| insulating part (mm) | | | | |
| Height of the projected | 0.4 | 0.2 | 0.1 | 0.04 |
| portion (mm) | | | | |
| Thickness of the part | 0.4 | 0.2 | 0.1 | 0.04 |
| to be supported | | | | |
| (one of the foked | | | | |
| portion) (mm) | | | | |

| | | | | |
|---|---|---|---|---|
| Shortest dearance between the | 0.5 mm | 0.25 mm | 0.125 mm | 0.05 mm |
| inner peripheral edge surface | × 0.25 | × 0.25 mm | × 0.25 mm | × 0.25 mm |
| of the through-hole in the frame | | | | |
| plate and the conductive part | | | | |
| for connection and ratio of the | | | | |
| shortest dearance in the | | | | |
| conductive part for connection | | | | |
| to the thickness | | | | |
| Ratio (S₂/S₁) | 0.2 | 0.2 | 0.2 | 0.2 |
| Ratio (V₁/V₂) | 0.4 | 0.4 | 0.4 | 0.4 |

### COMPARATIVE EXAMPLES 1 TO 4

Respective anisotropically conductive connectors were produced in the same manner as in Examples 1 to 4 except that the material of the frame plate (10) was changed to SUS304 (saturation magnetization: 0.01 Wb/m²).

The parts (25) to be supported in the elastic anisotropically conductive films (20) of the anisotropically conductive connectors thus obtained were observed. As a result, it was confirmed that the conductive particles were scarcely present in all the parts (25) to be supported.

### COMPARATIVE EXAMPLES 5 TO 8

Respective anisotropically conductive connectors were produced in the same manner as in Examples 1 to 4 except that the material of the frame plate (10) was changed to SUS304 (saturation magnetization: 0.01 Wb/m²), and a material prepared in the following manner was used as the molding material for forming the elastic anisotropically conductive films.

Molding material: 50 parts by weight of conductive particles having an average particle diameter of 20 μm were added to and mixed with 100 parts by weight of addition type liquid silicone rubber. Thereafter, the resultant mixture was subjected to a defoaming treatment by pressure reduction, thereby preparing a molding material for molding elastic anisotropically conductive films. In the above-described process, as the conductive particles, those (average amount coated: 20% by weight of the weight of core particles) obtained by plating the core particles formed of nickel with gold were used.

The parts (25) to be supported in the elastic anisotropically conductive films (20) of the anisotropically conductive connectors thus obtained were observed. As a result, it was confirmed that the conductive particles were scarcely present in all the parts (25) to be supported.

[Evaluation of Anisotropically Conductive Connector]

(1) Each of the anisotropically conductive connectors according to Examples 1 to 4 and Comparative Examples 1 to 8 was tested in the following manner.

Two electrode plates, on which electrodes had been formed in accordance with a pattern corresponding to the conductive parts for connection in the elastic anisotropically conductive film of each of the anisotropically conductive connectors, were provided. The anisotropically conductive connector was fixed in alignment to one electrode plate in a state positioned in such a manner that each of the conductive parts for connection in the elastic anisotropically conductive film thereof are located on the respective electrodes of the electrode plate, and the other electrode plate was fixed in alignment to the anisotropically conductive connector in a state positioned in such a manner that the respective electrodes thereof are located on the conductive parts for connection in the elastic anisotropically conductive film of the anisotropically conductive connector. The elastic anisotropically conductive film of the anisotropically conductive connector was then pressurized by the other electrode plate in such a manner that the distortion factor in the thickness-wise direction of the conductive parts for connection was 25%. In this state, an electric resistance (hereinafter referred to as “conduction resistance”) of each of the conductive parts for connection in the thickness-wise direction and an electric resistance (hereinafter referred to as “insulation resistance”) between adjacent conductive parts for connection were measured to find an average value and maximum value of the conduction resistance, and a minimum value of the insulation resistance. When the insulation resistance is lower than 1 kΩ, it is difficult to actually use such a anisotropically conductive connector.

The results thereof are shown in Table 3.

TABLE 3

| | Saturation | | | | Minimum |
|---|---|---|---|---|---|
| | magnetization | Pitch of | Conduction | | value of |
| | of frame | conductive | resistance (Ω) | | insulation |
| | plate (Wb/m²) | parts (mm) | Average value | Maximum value | resistance (Ω) |
| Example 1 | 1.4 | 2 | 0.03 | 0.04 | >10 M |
| Example 2 | 1.4 | 1 | 0.07 | 0.08 | >10 M |
| Example 3 | 1.4 | 0.5 | 0.16 | 0.17 | >10 M |
| Example 4 | 1.4 | 0.2 | 0.38 | 0.40 | >10 M |
| Comparative | 0.01 | 2 | 0.03 | 0.06 | 460 |
| Example 1 | | | | | |
| Comparative | 0.01 | 1 | 0.07 | 0.10 | 125 |
| Example 2 | | | | | |
| Comparative | 0.01 | 0.5 | 0.14 | 0.19 | 8 |
| Example 3 | | | | | |
| Comparative | 0.01 | 0.2 | 0.37 | 0.43 | 1 |
| Example 4 | | | | | |
| Comparative | 0.01 | 2 | 0.12 | 0.21 | 964 |
| Example 5 | | | | | |
| Comparative | 0.01 | 1 | 0.25 | 0.36 | 692 |
| Example 6 | | | | | |
| Comparative | 0.01 | 0.5 | 0.48 | 0.68 | 520 |
| Example 7 | | | | | |
| Comparative | 0.01 | 0.2 | 1.38 | 1.86 | 16 |
| Example 8 | | | | | |

As apparent from the results shown in Table 3, it was confirmed that according to the anisotropically conductive connectors of Examples 1 to 4, good conductivity is achieved in the conductive parts for connection, and necessary insulating property is achieved between adjacent conductive parts for connection in the elastic anisotropically conductive films even when the pitch among the conductive parts for connection is small.

(2) Each of the anisotropically conductive connectors according to Example 1 and Comparative Example 1 was tested in the following manner.

Two electrode plates, on which electrodes had been formed in accordance with a pattern corresponding to the conductive parts for connection in the elastic anisotropically conductive film of each of the anisotropically conductive connectors, were provided. The anisotropically conductive connector was fixed in alignment to one electrode plate in a state positioned in such a manner that each of the conductive parts for connection in the elastic anisotropically conductive film thereof are located on the respective electrodes of the electrode plate, and the other electrode plate was fixed in alignment to the anisotropically conductive connector in a state positioned in such a manner that the respective electrodes thereof are located on the conductive parts for connection in the elastic anisotropically conductive film of the anisotropically conductive connector.

The elastic anisotropically conductive film of the anisotropically conductive connector was then pressurized by the other electrode plate under an environment of 25° C. and relative humidity of 30% in such a manner that the distortion factor in the thickness-wise direction of the conductive parts for connection was 25%. After the anisotropically conductive connector was left to stand for 1 second in this state, the other electrode plate was separated from the elastic anisotropically conductive film of the anisotropically conductive connector, and the elastic anisotropically conductive film of the anisotropically conductive connector was pressurized by the other electrode plate after additional 2 seconds had elapsed. This process was regarded as a cycle, and the cycle was repeated 5,000 times in total to measure a surface potential of the elastic anisotropically conductive film of the anisotropically conductive connector within 40 seconds.

The measurement of the surface potential in the above-described process was conducted by using a surface potential meter “Model 520” manufactured by TREK JAPAN on 4 locations A to D in the functional part 21 of the elastic anisotropically conductive film 20 as illustrated in FIG. 18.

If the surface potential is 50 V or higher, for example, a circuit device to be inspected may possibly incur adverse influence such as breakdown in the inspection of the circuit device.

The results thereof are shown in Table 4.

TABLE 4

Surface potential (V)
Location of measurement

| | A | B | C | D |
|---|---|---|---|---|
| Example 1 | 11 | 20 | 23 | 12 |
| Comparative | 80 | 130 | 117 | 78 |
| Example 1 | | | | |

As apparent from the results shown in Table 4, it was confirmed that according to the anisotropically conductive connector of Example 1, the value of the surface potential of each of the measured locations A to D is lower than 50 V, and so electric charges can be inhibited from being accumulated on the surface of the elastic anisotropically conductive film even when it was used for a long period of time, thereby exclude the adverse influence by static electricity.

On the other hand, the value of the surface potential of each of the measured locations A to D was 50 V or higher in the anisotropically conductive connector of Comparative Example 1, and the surface of the elastic anisotropically conductive film was charged with electric charges by using it for a long period of time.

According to the anisotropically conductive connectors of the present invention, they are hard to be deformed and easy to handle because the part to be supported is formed at the peripheral edge of the functional part having the conductive parts for connection, and this part to be supported is fixed to the inner peripheral edge portion about the through-hole in the frame plate. In addition, the positioning mark is formed in, for example, the frame plate, whereby the positioning and the holding and fixing to a circuit device to be connected can be easily conducted upon an electrically connecting operation to the circuit device.

Since the anisotropically conductive connector of the present invention is obtained by subjecting the molding material layer(s) to the curing treatment in the formation of the elastic anisotropically conductive film(s) thereof in a state that the conductive particles present in the portion(s) to become the part(s) to be supported in the molding material layer(s) have been retained in those portion(s) to become the part(s) to be supported by applying a magnetic field to those portion(s), the conductive particles present in the portion(s) to become the part(s) to be supported in the molding material layer(s), i.e., portion(s) located above and below the inner peripheral edge portion(s) about the through-hole(s) in the frame plate 10 are not gathered at the portion(s) to become the conductive part(s) for connection. As a result, the conductive particles are prevented from being contained in excess in the conductive parts for connection located most outside among the conductive parts for connection in the resulting elastic anisotropically conductive film(s). Accordingly, there is no need of reducing the content of the conductive particles in the molding material layer(s), so that good conductivity is achieved with certainty in all the conductive parts for connection in the elastic anisotropically conductive film(s), and moreover insulating property between adjacent conductive parts for connection can be achieved with certainty.

Since thermal expansion in the plane direction of each elastic anisotropically conductive film is restrained by the frame plate, a good electrically connected state to a circuit device to be connected can be stably retained even when it is subjected to thermal hysteresis by temperature change by using a material having a low coefficient of linear thermal expansion as that for forming the frame plate.

According to the structure that the conductive part for charge elimination is formed in the part to be supported in the elastic anisotropically conductive film, the conductive part for charge elimination is electrically connected to the ground through the frame plate, whereby static electricity generated on the surface of the elastic anisotropically conductive film is eliminated through the conductive part for charge elimination. As a result, it can be prevented or inhibited that electric charges are accumulated on the surface of the elastic anisotropically conductive film, so that adverse influence by static electricity can be excluded.

According to the probe member of the present invention, positioning, and holding and fixing to a circuit device as an object of inspection can be conducted with ease even when the pitch of electrodes to be inspected of the circuit device is small, and high reliability on connection to each electrode to be inspected is achieved because the probe member has the anisotropically conductive connector described above.

According to the electrical inspection apparatus for circuit devices of the present invention, positioning, and holding and fixing to a circuit device as an object of inspection can be conducted with ease even when the pitch of electrodes to be inspected of the circuit device is small, and high reliability on connection to each electrode to be inspected is achieved because the electrical connection to the electrodes to be inspected of the circuit device is attained through the probe member having the anisotropically conductive connector described above.

According to the conductive connection structure of the present invention, high reliability on connection is achieved because the electrical connection is made through the anisotropically conductive connector described above.

What is claimed is:

1. A process for producing an anisotropically conductive connector comprising a frame plate having a through-hole extending in a thickness-wise direction thereof and an elastic anisotropically conductive film arranged within the through-hole in the frame plate and supported by the inner peripheral edge portion about the through-hole, in which the elastic anisotropically conductive film is composed of a functional part composed of a conductive part for connection containing conductive particles exhibiting magnetism at high density and extending in a thickness-wise direction of the film and an insulating part formed around the conductive part, and a part to be supported integrally formed at a peripheral edge of the functional part and fixed to the inner peripheral edge portion about the through-hole in the frame plate, the process comprises the steps of:
forming a molding material layer for the elastic anisotropically conductive film with conductive particles exhibiting magnetism dispersed in a liquid polymeric substance-forming material, which will become an elastic polymeric substance by a curing treatment, within the through-hole in the frame plate and at the inner peripheral edge portion about the through-hole,
applying a magnetic field having higher intensity at a portion to become the conductive part for connection and a portion to become the part to be supported, than any other portion, to the molding material layer, thereby gathering the conductive particles in the molding material layer at the portion to become the conductive part for connection in a state that at least the conductive particles present in the portion to become the part to be supported in the molding material layer have been retained in this portion, and orienting them in the thickness-wise direction, and in this state,
subjecting the molding material layer to a curing treatment to form the elastic anisotropically conductive film.

2. The production process of the anisotropically conductive connector according to claim 1, wherein a frame plate having a plurality of through-holes is used, and elastic anisotropically conductive films are formed in the respective through-holes in the frame plate.

3. The production process of the anisotropically conductive connector according to claim 1 or 2, wherein an elastic anisotropically conductive film having a functional part, in which a plurality of conductive parts for connection are arranged in a state mutually insulated by an insulating part, is formed.

4. The production process of the anisotropically conductive connector according to any one of claims 1 to 3, wherein the frame plate exhibits magnetism at least at the inner peripheral edge portion about the through-hole, and the inner peripheral edge portion about the frame plate is magnetized, thereby applying a magnetic field to the portion to become the part to be supported of the molding material layer.

5. The production process of the anisotropically conductive connector according to claim 4, wherein the inner peripheral edge portion about the through-hole in the frame plate has a saturation magnetization of at least 0.1 Wb/m².

6. The production process of the anisotropically conductive connector according to claim 4 or 5, wherein the frame plate is formed by a magnetic substance.

7. The production process of the anisotropically conductive connector according to any one of claims 1 to 6, wherein the frame plate has a coefficient of linear thermal expansion of at most 3×10⁻⁵/K.

8. The production process of the anisotropically conductive connector according to any one of claims 1 to 7, wherein the through-hole in the frame plate satisfies the following expression (1):
0.02≦(S₂/S₁)≦0.5 Expression (1)
wherein S₁ is a sectional area in a plane direction of the through-hole, and S₂ is a total sectional area in a plane direction of the conductive part(s) for connection in the elastic anisotropically conductive film formed in the through-hole.

9. The production process of the anisotropically conductive connector according to any one of claims 1 to 8, wherein the shortest clearance between an inner peripheral edge surface of the through-hole in the frame plate and a conductive part for connection to be formed is at least 0.25 times as much as the thickness of the conductive part for connection.

10. The production process of the anisotropically conductive connector according to any one of claims 1 to 9, wherein conductive particles having a saturation magnetization of at least 0.1 Wb/m² are used.

11. The production process of the anisotropically conductive connector according to any one of claims 1 to 10, wherein the following expression (2) is satisfied:
0.1≦(V₁/V₂)≦0.5 Expression (2)
wherein V₁ is a total volume of the conductive particles contained in the molding material layer, and V₂ is a total volume of the conductive part(s) for connection in the elastic anisotropically conductive film to be formed.

12. The production process of the anisotropically conductive connector according to any one of claims 1 to 11, wherein a magnetic flux density at the portion to become the part to be supported in a state that the magnetic field is being applied to the molding material layer is 30 to 150% of a magnetic flux density at the portion to become the conductive part for connection.

13. The production process of the anisotropically conductive connector according to any one of claims 1 to 12, wherein a magnetic field is applied to the portion to become the part to be supported in the molding material layer, whereby the molding material layer is subjected to a curing treatment in a state that the conductive particles present at least in the portion to become the part to be supported are oriented in the thickness-wise direction, to form an elastic anisotropically conductive film having a conductive part for charge elimination in the part to be supported.

14. An anisotropically conductive connector produced in accordance with the production process according to any one of claims 1 to 13.

15. A probe member suitable for use in electrical inspection of a circuit device, which comprises:
the anisotropically conductive connector according to claim 14, which has elastic anisotropically conductive films, in which conductive parts have been formed in accordance with a pattern corresponding to a pattern of electrodes to be inspected of the circuit device as an object of inspection.

16. The probe member according to claim 15, comprising a circuit board for inspection, on the surface of which inspection electrodes have been formed in accordance with a pattern corresponding to a pattern of electrodes to be inspected, the anisotropically conductive connector arranged on the surface of the circuit board for inspection and a sheet-like connector arranged on the surface of the anisotropically conductive connector,
wherein the sheet-like connector is composed of an insulating sheet and a plurality of electrode structures each extending through in a thickness-wise direction of the insulating sheet and arranged in accordance with a pattern corresponding to the pattern of the electrodes to be inspected.

17. An electrical inspection apparatus for circuit devices, comprising the probe member according to claim 15 or 16, wherein electrical connection to electrodes to be inspected of a circuit device as an object of inspection is achieved through the probe member.

18. The electrical inspection apparatus for circuit devices according to claim 17, which has a heating means for heating the circuit device as the object of inspection, and wherein the electrical inspection of the circuit device is carried out in a state that the circuit device has been heated to a prescribed temperature by the heating means.

19. A conductive connection structure obtained by being electrically connected through the anisotropically conductive connector according to claim 14.
